(19) United States
(12) Patent Application Publication
(10) Pub. No.: US 2026/0204903 A1
(43) Pub. Date: Jul. 16, 2026

(54) FAULT MANAGED POWER OUT-OF-BAND SYNCHRONIZATION BETWEEN POWER TRANSMITTERS AND POWER RECEIVERS

(71) Applicant: Cisco Technology, Inc., San Jose, CA (US)

(72) Inventors: Joel Richard Goergen, Soulsbyville, CA (US); Chad M. Jones, Doylestown, OH (US); Jason Dewayne Potterf, Austin, TX (US); Elizabeth Kochuparambil, Morgan Hill, CA (US); Matthew Stroud, Allen, TX (US); Kameron Rose Hurst, Sonora, CA (US); George Allan Zimmerman, Manhattan Beach, CA (US)

(21) Appl. No.: 19/092,219

(22) Filed: Mar. 27, 2025

Related U.S. Application Data
(60) Provisional application No. 63/745,073, filed on Jan. 14, 2025.

(51) Int. Cl. H02J 3/00; H02J 50/10

(52) U.S. Cl. CPC H02J 3/001; H02J 50/10

(57) ABSTRACT

Out-of-band synchronization between a power transmitter and one or more power receivers. A system comprise a power transmitter; a power receiver; a power cable connected between the power transmitter and the power receiver; and a synchronization cable connected between the power transmitter and the power receiver. The power transmitter is configured to transmit over a pair of lines in the power cable to the power receiver, and to perform a safety check to detect a fault with respect to the pair of lines. The power transmitter includes a transmitter synchronization circuit and the power receiver includes a receiver synchronization circuit in communication with the transmitter synchronization circuit of the power transmitter via the synchronization cable. The transmitter synchronization circuit is configured to generate a synchronization clock signal sent to the receiver synchronization circuit via the synchronization cable.

### CROSS-REFERENCE TO RELATED APPLICATION

This application claims priority to U.S. Provisional Application No. 63/745,073, filed Jan. 14, 2025, the entirety of which is incorporated herein by reference.

### TECHNICAL FIELD

The present disclosure relates to fault managed power distribution techniques.

### BACKGROUND

Present power fault methods for alternating current (AC) and direct current (DC) powering systems rely on circuit breaker devices to trip faults and conduit or other cable protection methods to prevent humans from touching any wiring. For fault managed power systems, a set of field effect transistors (FETs) are used to shut off power when a fault is detection. Fault managed power solutions are compact, cost effective for enterprise applications, and easily combine with digital communications.

### BRIEF DESCRIPTION OF THE DRAWINGS

FIG. 1A is a simplified block diagram of a fault managed power (FMP) power distribution system employing channel isolation techniques according to an example embodiment.

FIG. 1B illustrates an FMP power distribution system similar to that shown in FIG. 1A, but further including channel isolation on the receiver side, according to an example embodiment.

FIG. 2 is a schematic diagram of a power transmitter and rail voltage converter that employs a step-down transformer arrangement at a power receiver, according to an example embodiment.

FIG. 3 is a block diagram of a power distribution system that employs a “digital fuse” fault detector at the transmit side and receive side, according to an example embodiment.

FIG. 4A is a schematic diagram of a digital fuse fault detector associated with a power transmitter, according to an example embodiment.

FIG. 4B illustrates an example block diagram of a digital signal processor used in the digital fuse fault detector, according to an example embodiment.

FIG. 4C shows a voltage waveform that depicts the operation of the digital fuse fault detector, according to an example embodiment.

FIG. 5A shows a block diagram of a power distribution system that employs power pulsing fault detection techniques, according to an example embodiment.

FIG. 5B illustrates a diagram generally depicting operation of the power pulsing fault detection techniques, according to an example embodiment.

FIG. 5C is a flow chart depicting a method according to an example embodiment.

FIG. 6 is a block diagram of a power distribution system configured to be deployed in a confined space, housing or “box” (or chassis) and employing power distribution via a bus bar, according to an example embodiment.

FIG. 7 is a block diagram depicting how a digital fuse fault detector may be arranged to detect faults on a bus bar, such as in the system shown in FIG. 6, according to an example embodiment.

FIG. 8A is a block diagram of a power distribution system in a modular chassis arrangement, according to an example embodiment.

FIG. 8B is a block diagram of a datacenter power distribution system that is configured to support fault managed power techniques, according to an example embodiment.

FIG. 9 is a diagram of a power shelf that may be used in the various power distribution systems presented herein, according to an example embodiment.

FIG. 10A shows a receive side of a power system that is configured to exploit a current share bus to perform various functions for fault managed power control, according to an example embodiment.

FIG. 10B illustrates a voltage versus current curve that depicts operations of the current share bus employed in the fault managed power techniques, according to an example embodiment.

FIG. 10C is a diagram depicting a control loop for the current share bus, according to an example embodiment.

FIGS. 10D and 10E are curves that depict examples of use of the current share bus to selectively inhibit operation of one or more of a plurality of power supply units in the system of FIG. 10A to achieve a desired power efficiency, according to an example embodiment.

FIG. 10F illustrates a control flow that may be employed in the system of FIG. 10A for the examples shown in FIGS. 10D and 10E, according to an example embodiment.

FIG. 11 is a block diagram of a portion of a power distribution system that may be configured to employ the current share bus techniques to selectively inhibit operation of one or more power transmitters, according to an example embodiment.

FIGS. 12A and 12B are block diagrams of power distribution systems that may be configured to employ current share bus techniques on both the power transmitter side and power receiver side, according to an example embodiment.

FIG. 12C shows a block diagram of a digital signal processor controller configured to support the power distribution systems depicted in FIGS. 12A and 12B, according to an example embodiment.

FIG. 12D is a flow chart depicting a method according to an example embodiment.

FIG. 13 is a block diagram of a power distribution system similar to that of FIG. 5A, but further including an additional cable to carrying a synchronization signal (clock) between a power transmitter and a power receiver, according to an example embodiment.

FIG. 14 is a simplified block diagram of the relevant components of a power transmitter and a power receiver to enable the out-of-band synchronization techniques, according to an example embodiment.

FIG. 15A is a block diagram of a transmit sync block used in a power transmitter to enable the out-of-band synchronization techniques, according to an example embodiment.

FIG. 15B is a block diagram of a receive sync block used in a power receiver to enable the out-of-band synchronization techniques, according to an example embodiment.

FIG. 15C illustrates a flow diagram depicting the cooperative operation of the transmit sync block and receive sync block for synchronization, authentication and security verification, according to an example embodiment.

FIG. 16 is a flow chart depicting techniques for synchronization fault detection operations of a power transmitter with fault detection operations of a power receiver, according to an example embodiment.

FIG. 17A is a block diagram of a multi-drop power distribution system that is configured to support the out-of-band synchronization techniques, according to an example embodiment.

FIG. 17B shows a block diagram of a power receiver for the multi-drop power distribution system of FIG. 17A, and configured to support the out-of-band synchronization techniques, according to an example embodiment.

FIGS. 17C, 17D and 17E illustrate the state of the power receivers in the multi-drop power distribution system of FIG. 17A during stages of operation to support the out-of-band synchronization techniques, according to an example embodiment.

### DETAILED DESCRIPTION

### Overview

In one embodiment, techniques are provided for out-of-band synchronization between a power transmitter and a power receiver. For example, a system is provided comprising: a power transmitter; a power receiver; a power cable connected between the power transmitter and the power receiver; and a synchronization cable connected between the power transmitter and the power receiver. The power transmitter is coupled to receive Direct Current (DC) power and to transmit power, derived from the DC power, over a pair of lines in the power cable to the power receiver, the power transmitter further configured to perform a safety check to detect a fault with respect to the pair of lines. The power receiver is configured to receive power from the pair of lines in the power cable, and configured to perform a safety check to detect a fault with respect to the pair of lines. Furthermore, the power transmitter includes a transmitter synchronization circuit and the power receiver includes a receiver synchronization circuit in communication with the transmitter synchronization circuit of the power transmitter via the synchronization cable, wherein the transmitter synchronization circuit is configured to generate a synchronization clock signal sent to the receiver synchronization circuit via the synchronization cable.

In another embodiment, a method is provided comprising: connecting a power cable between a power transmitter and a power receiver; connecting a synchronization cable between the power transmitter and the power receiver; transmitting, by the power transmitter, power over a pair of lines in the power cable to the power receiver and performing a safety check on the pair of lines at the power transmitter; receiving, by the power receiver, the power over the pair of lines in the power cable from the power transmitter, and performing a safety check to detect a fault with respect to the pair of lines at the power receiver; transmitting, by the power transmitter over the synchronization cable, a synchronization clock signal to the power receiver; receiving, by the power receiver over the synchronization cable, the synchronization clock signal from the power transmitter; and synchronizing fault detection operations of the safety check performed by the power receiver with respect to fault detection operations of the safety check performed by the power transmitter.

In still another embodiment, a system is provided comprising: a power transmitter configured to output a power waveform, the power transmitter including a transmitter synchronization circuit and a transmitter safety check circuit, the transmitter synchronization circuit configured to generate a synchronization clock signal that synchronizes operation of the transmitter safety check circuit; a plurality of power receivers connected in a multi-drop arrangement, a first power receiver of the plurality of power receivers being connected to the power transmitter; a power cable including a pair of conductors to carry power from the power transmitter to the first power receiver; and a synchronization cable including a pair of conductors to carry the synchronization clock signal from the power transmitter to the first power receiver. Each power receiver of the plurality of power receivers includes: differential power inputs to receive the power waveform; differential power outputs to output the power waveform to a downstream power receiver of the plurality of power receivers; a receiver safety check circuit; differential synchronization inputs to receive the synchronization clock signal for use by the receiver safety check circuit; differential synchronization outputs to output the synchronization clock signal to a downstream power receiver; and a receiver synchronization circuit that controls the receiver safety check circuit based on the synchronization clock signal.

### EXAMPLE EMBODIMENTS

### FMP Channel Isolation

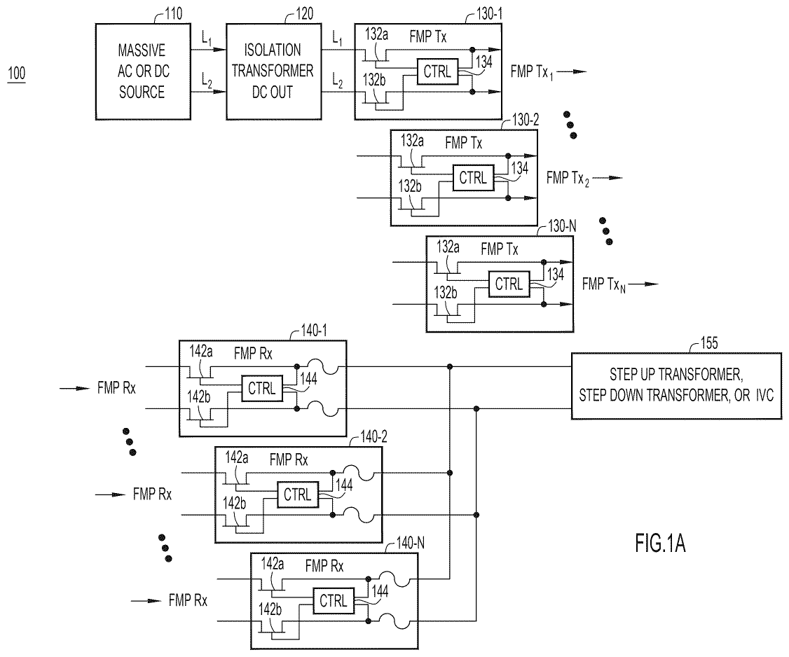

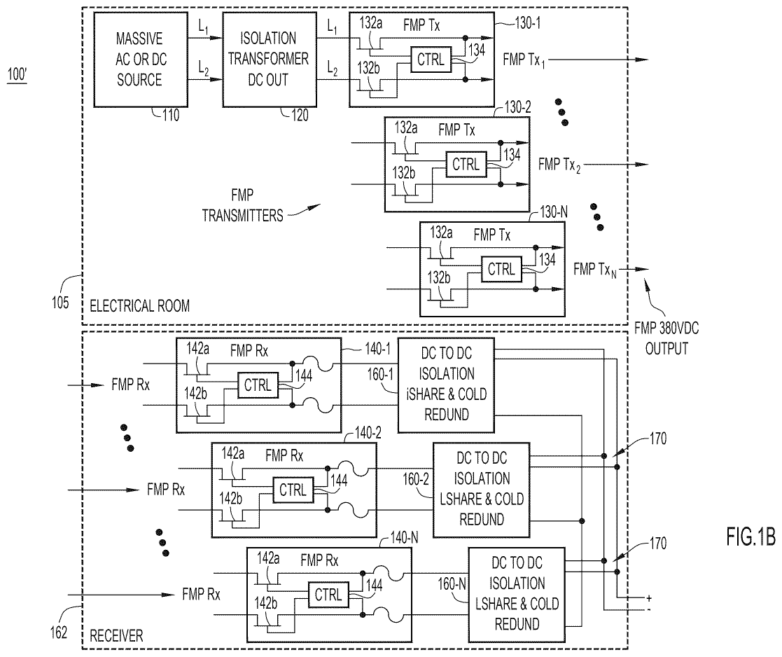

Referring first to FIG. 1A, a simplified block diagram is shown of a fault managed power (FMP) power distribution system 100 employing channel isolation techniques according to an example embodiment. The power distribution system 100 includes a power source 110 configured to output electrical power over a pair of lines L1 and L2. One or more isolation transformers 120 are coupled to the power source 110 and configured to output Direct Current (DC) power. A plurality of power transmitters 130-1, 130-2, . . . , 130-N are coupled to receive the isolated DC power and a plurality of power receivers 140-1, 140-2, . . . , 140-N are provided, each configured to receive power from over a respective cable that includes a pair of lines from an associated power transmitter of the plurality of power transmitters. The power source may be a massive AC or DC power source.

Each power transmitter 130-1 to 130-N is configured to transmit power, derived from the DC power, over an associated pair of lines. Moreover, each power transmitter includes field effect transistor (FET) switches 132a and 132b connected to lines L1 and L2, respectively, and a control (CTRL) block 134 configured to perform a safety check on the DC power received via the isolation transformer(s) 120 on the Lines L1 and L2, to detect a fault with respect to the associated pair of lines. When and if the CTRL block 134 detects a fault, power is disconnected by field effect transistor (FET) switches 132a and 132b and the pair of lines L1 and L2, so that power is shut down and not transmitted by the associated power transmitter.

Similarly, each power receiver 140-1 to 140-N is configured to output power over a pair of output lines, and includes FET switches 142a and 142b and a CTRL block 144 configured to perform a safety check to detect a fault with respect to a pair of lines over which it receives power. When the CTRL block 144 of the power receiver detects a fault, it controls the FET switches 142a and 142b in the power receiver to disconnect from the pair of lines so that power is not output from the power receiver.

Examples of fault detection and control techniques that may be employed at the power transmitters and the power receivers are described further below.

Furthermore, as shown at 150, respective output lines of the pair of output lines of the plurality of power receivers are connected to each other. Thus, the one or more isolation transformers 120 achieve channel isolation at the transmit side. There may be no need to do isolation at the receive side, for certain applications. There may be no need to perform fault detection at the receiver in some applications.

As shown in FIG. 1A, the output of the power receivers 140-1 to 140-N may be connected to a step-down transformer, a step-up transformer or other devices depending on the power application at the receive side, as shown at 155 as described further below.

FIG. 1B illustrates an FMP power distribution system 100′ that is a variation of the power distribution system 100 shown in FIG. 1A. The power distribution system 100′ includes a power source 110 configured to output electrical power over a pair of lines L1 and L2, one or more isolation transformers 120 coupled to the power source 110 and configured to output Direct Current (DC) power, and a plurality of power transmitters 130-1 to 130-N, similar to the arrangement shown in FIG. 1A. All of these components may be located/deployed in an electrical room shown at reference numeral 105.

Each of the plurality of power receivers 140-1 to 140-N is connected to a corresponding one of DC-to-DC isolation circuits 160-1, 160-2, . . . , 160-N, respectively, and the outputs of the DC-to-DC isolation circuits 160-1 to 160-N may be connected together, as shown at referenced numeral 170. The power receivers 140-1 to 140-N and the DC-to-DC isolation circuits 160-1 to 160-N may be positioned in a power shelf 162 in a chassis of a rack in a datacenter.

Thus, FMP power distribution system 100′ has isolation at the transmit side and at the receive side. This arrangement can provide isolated and regulated power. Moreover, the iShare and cold redundancy (redund) capabilities at the power receivers, indicated in FIG. 1B, can provide additional control fidelities, as described in more detail below.

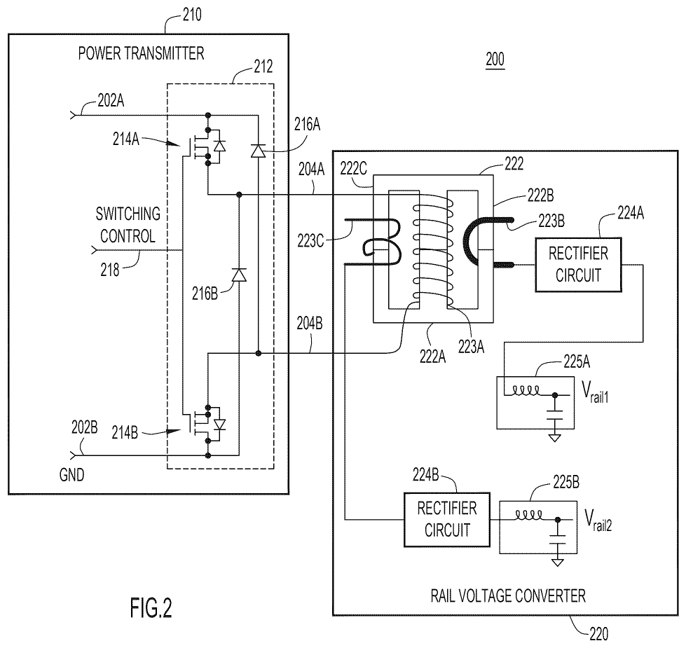

Turning now to FIG. 2, a power system 200 is shown that includes a power transmitter and rail voltage converter, for purposes of explaining an example step down transformer arrangement that may be used in accordance with the examples presented herein. The power system 200 has a power transmitter 210 that includes a switching circuit 212 that is optional and used when the power transmitter 210 is of a type that provides a continuously-on power waveform. The switching circuit 212 resides between power transmitter outputs 202A and 202B and a wire pair comprising wires 204A and 204B. The switching circuit 212 includes a first FET switch 214A and a second FET switch 214A. The first FET switch 214A is connected between the power transmitter output 202A and the wire 204A and the second FET switch 214B is connected between the power transmitter output 202B and the wire 204B. In addition, the switching circuit 212 may include a first diode 216A connected between power transmitter output 202A and the second FET switch 214B, and a second diode 216B connected between power transmitter output 202B and the first FET switch 214A. The switching circuit 212 further includes a switching control input 218 that is connected to the first FET switch 214A and the second FET switch 214B. The power transmitter 210 (or a separate controller) provides a control waveform to the switching control input 218 to alternatingly switch the first and second FET switches 214A and 214B on and off so as to generate power waveform that alternates between power-on times and power off-times. The power waveform is provided to the wires 204A and 204B. In one example, the control waveform is an 8 V waveform that has 15%/85% on/off duty cycle. As mentioned above, the switching circuit 212 is not needed if the power transmitter 210 generates a power waveform that inherently switches between on-times and off-times. In one example, the voltage level of the power waveform is 380 VDC.

The power system 200 has a rail voltage converter 220 that includes transformer 222. The example arrangement of the rail voltage converter 220 can generate two different DC rail voltages through the use of a first rectifier circuit 224A and a second rectifier circuit 224B, as an example. The transformer 222 is a three-monument transformer that includes a central monument 222A and a primary winding 223A around the central monument, a first secondary monument 222B and a first secondary winding 223B around the first secondary monument 222B, and a second secondary monument 222C and a second secondary winding 223C around the second secondary monument 222C. In one example, the primary winding 223A has 100 turns of 28-gauge American Wire Gauge (AWG) wire, the first secondary winding 223B is one turn of copper foil (1.4 inches wide) and the second secondary winding is two turns of 0.25 in wide copper foil. The number of turns of the primary winding 223A can be adjusted to achieve the desired output voltage level from the transformer. The transformer 222 steps down the voltage (e.g., 300 V or more) of the power waveform supplied to the primary winding 223A in a single step, to a substantially lower voltage level suitable for providing rail voltage power to an integrated circuit.

The wire pair consisting of wires 204A and 204B are connected to opposite ends of the primary winding 223A to provide the power waveform to the transformer. In this example, the transformer 222 provides a first output waveform to first secondary winding 223B and a second output waveform to the second secondary winding 223C. The first rectifier circuit 224A has an input that is connected to the first secondary winding 223B, and the second rectifier circuit 224B has an input that is connected to the second secondary winding 223C.

The first rectifier circuit 224A converts the first output waveform from the first secondary winding 223B to a DC voltage. An inductor-capacitor filter 225A may be provided at the output of the first rectifier circuit 224A to filter the output of the first rectifier circuit 224A to produce a first DC rail voltage, Vᵣₐᵢₗ₁. Similarly, the second rectifier circuit 224B converts the second output waveform from the second secondary winding 223C to a second DC voltage. An inductor-capacitor filter 225B may be provided at the output of the first rectifier circuit 224B to filter the output of the first rectifier circuit 224B to produce a second DC rail voltage, Vᵣₐᵢₗ₂. The first and second rectifier circuits 224A and 224B may be DC bridge diodes or field effect transistor (FET) rectifier circuits.

The transformer 222 and associated circuitry in the rail voltage converter 220 can be compact and achieve a relatively high current output with high efficiency. For example, the rail voltage converter 220 can be implemented in a space of 10 mm by 40-60 mm by 30 mm, or smaller. The transformer 222 achieves the desired electrical isolation and thus there is no need for additional isolation circuitry in the rail voltage converter 220.

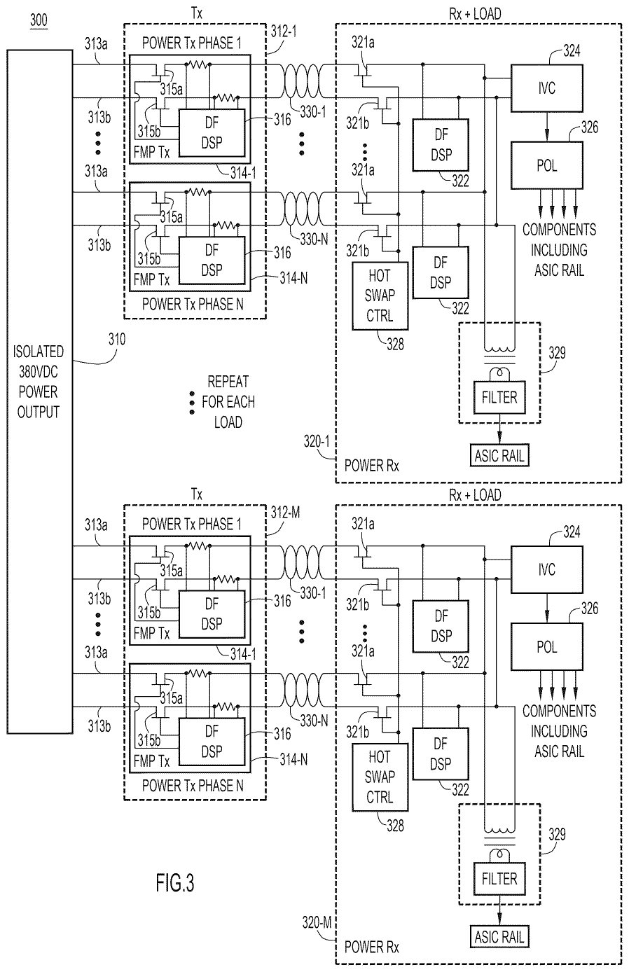

Reference is now made to FIG. 3 for a description of one example of a power distribution system that employs a “digital fuse” (DF) fault detection technique. The power distribution system 300 includes, in this example, an isolated (380 Volts DC (VDC)) power source 310, a plurality of power transmitters 312-1 to 312-M. Each power transmitter 312-1 to 312-M comprises N FMP transmitters 314-1 to 314-N to output N phases of power.

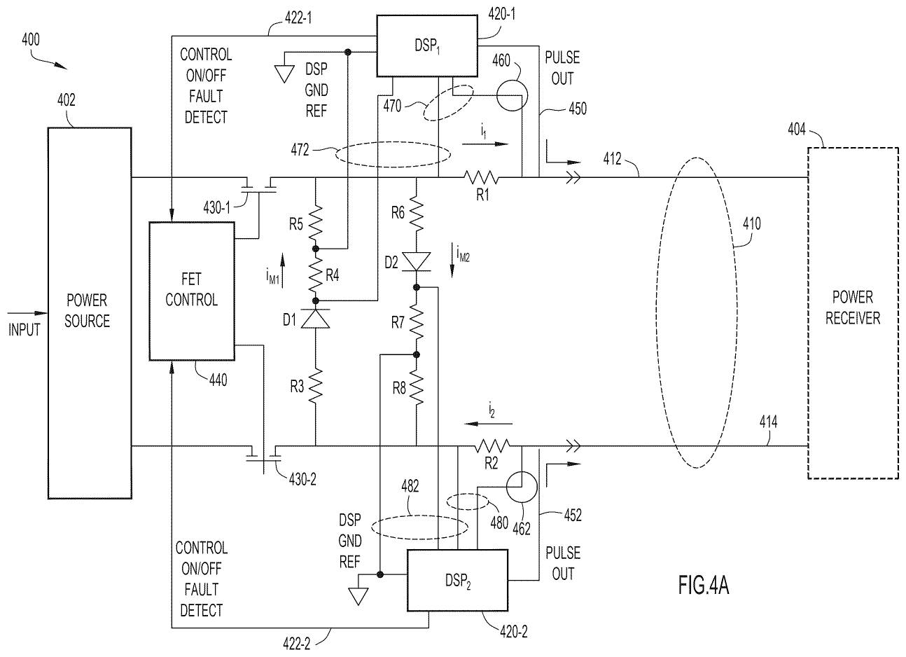

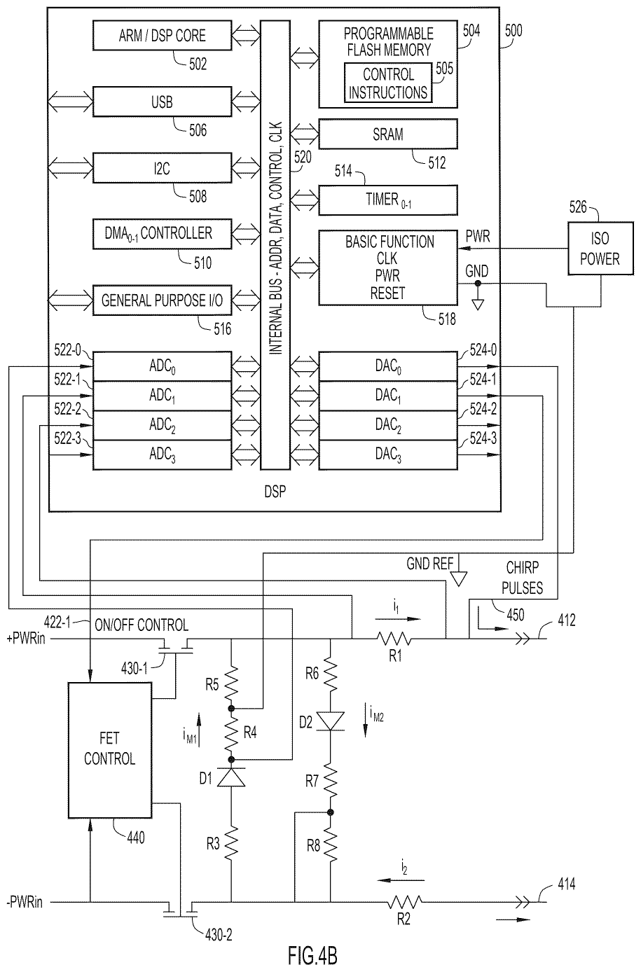

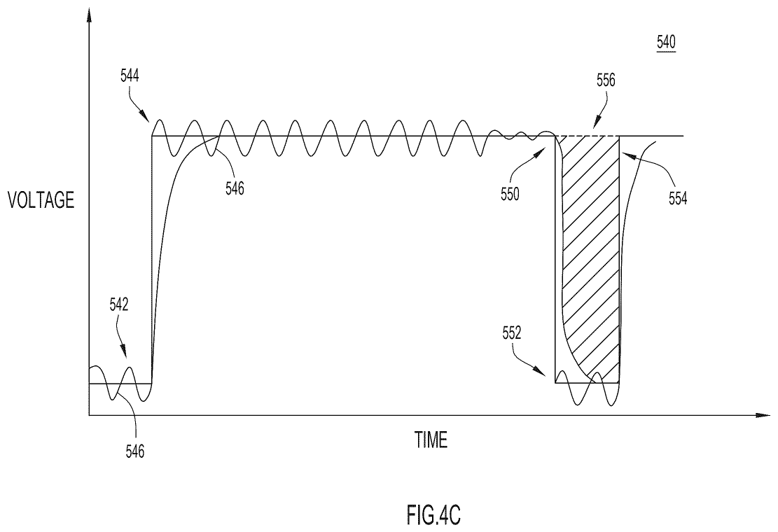

Each FMP transmitter 314-1 to 314-N includes a pair of FET switches 315a and 315b connected to an associated wire of a wire pair comprised of wires 313a and 313b. A DF digital signal processor (DSP) 316 is connected to the wires 313a and 313b and to the FET switches 315a and 315b. The DF DSP 316 controls FET switches 315a and 315b to connect/disconnect the DC power from being transmitted at its output when the DF DSP 316 detects a fault. The details of the DF DSP 316 are described below in connection with FIGS. 4A-4C.

The power distribution system 300 further includes a plurality of power receivers 320-1 to 320-M, each associated with a given load, and each coupled by N cables/wire pairs 330-1 to 330-N for each of the N phases of power from the N FMP transmitters of a power transmitter. Each power receiver 320-1 to 320-M includes, for each phase, FET switches 321a and 321b and a DF DSP 322. In addition, each power receiver 320-1 to 320-N includes an intermediate voltage controller (IVC) 324 connected to a point-of-load (POL) 326 that is configured to provide power supply voltage to one or more components, such as a rail voltage for an application integrated circuit (ASIC). Further still, each power receiver 320-1 to 320-M may include a hot swap controller (CTRL) 328 that facilitates connection/disconnection of loads from the power receiver, and transformer and filter circuitry 329, similar to that shown in FIG. 2, to output an ASIC rail voltage. The hot swap CTRL 328 is connected to the FET switches 321a and 321b for each phase, and though not specifically shown in the figure, the DF DSP 322 are connected to the FET switches 321a and 321b for each respective phase. The hot swap controller 328 may also generate the switching waveform for the transformer in the transformer and filter circuitry 329.

Reference is now made to FIGS. 4A and 4B. FIG. 4A is a schematic diagram of digital fuse 400 associated with a power transmitter, i.e., DF DSP 316 depicted in FIG. 3, for example, which is supplying power to a power receiver 404. The DF DSP 322 on the power receiver side may have a similar arrangement. The digital fuse 400 is configured to connect between a power source 402 and wires of cable 410, and in particular to the send wire 412 and to the return wire 414. The digital fuse 400 may include first and second digital signal processors (DSPs) 420-1 and 420-2. DSP 420-1 is coupled to the send wire 412 and DSP 420-2 is coupled to the return wire 414. It should be understood that a single DSP (with appropriate isolation circuitry) could be used to handle signals to/from the send wire 412 and the return wire 414 instead of two DSPs as shown in FIG. 4A. The digital fuse 400 further includes, or connects to, field effect transistor (FET) switches 430-1 and 430-2 and a FET control circuit 440. The FET control circuit 440 receives as input a control output 422-1 from both DSP 420-1 and a control output 422-2 from DSP 420-2. The switch 430-1 is connected between the power source 402 and the send wire 412 and the switch 430-2 is connected between the power source 402 and the return wire 414. The send current is shown as i₁ through resistor R1 on the send wire 412. The return current is shown as i₂ through resistor R2 on the return wire 414.

DSP 420-1 is configured to continuously inject chirp pulses onto the send wire 412 as shown at reference numeral 450. The chirp pulses from DSP 420-1 travel down the send wire 412 to the power receiver and come back on the return wire 414 through resistor R2 and through resistor R3 and diode D1 as current i_{M1} and then splits at resistors R4 and R5. Likewise, DSP 420-2 is configured to continuously inject chirp pulses onto the return wire 414 as shown at reference numeral 452. The chirp pulses from DSP 420-2 travel down the return wire 414 to the power receiver and come back on the send wire 412 through resistor R1 and through resistor R6 and diode D2 as current i_{M2} and then splits at resistors R7 and R8.

DSP 420-1 measures the signal on the send wire 412, via connection 460, resulting from the chirp pulses that it sends out. Similarly, DSP 420-2 measures the signal on the return wire 414, via connection 462, resulting from the chirp pulses that it sends out. In addition, the DSP 420-1 measures current on the connections as shown at 470 and measures voltage on the connections shown at 472. Likewise, the DSP 420-2 measures current on the connections as shown at 480 and measures voltage on the connections shown at 482.

FIG. 4B illustrates an example block diagram of a DSP 500 and its connections to the circuitry in a digital fuse. The DSP 500 may be used for either or both of DSP 420-1 and 420-2 shown in FIG. 4A. In one non-limiting example, the DSP 500 may be based on an ARM core processor, such as a signal processor manufactured by ST Microelectronics, e.g., STM32F336xC/E. “ARM” is formerly an acronym for Advanced Reduced Instruction Set Computer (RISC) Machines and originally Acorn RISC Machine) and is a family of RISC instruction set architectures (ISAs) for computer processors. The DSP 500 includes an ARM/DSP core processor 502, programmable flash memory 504 that stores control instructions 505 (firmware) that are executed by the core processor 502 to perform the various operations described herein, a Universal Serial Bus (USB) 506, an I2C serial bus 508, a direct memory access (DMA) controller 510, synchronous random access memory (SRAM) 512, timer 514, general purpose input/output (I/O) 516, a basic functions block 518 (for clock (clk), power, and reset), and an internal bus 520 for address, data control and clock. The DSP 500 further includes a block analog-to-digital converters (ADCs) and a block of digital-to-analog converters (DACs). The number of ADCs and DACs may vary depending on the particular DSP. In one example, the DSP 500 includes four ADCs 522-0, 522-1, 522-2 and 522-3 and four DACs 524-0, 524-1, 524-2 and 524-3. The ADCs 522-0 to 522-3 receive input signals from the digital fuse circuitry and the DACs 524-0 to 524-3 are used to provide output signals to the digital fuse circuitry. Power is provided to the DSP via ISO power 526.

In at least one embodiment, processor 502 is at least one hardware processor configured to execute various tasks, operations and/or functions for DSP 500 as described herein according to software and/or instructions configured for DSP 500. Processor 502 (e.g., a hardware processor) can execute any type of instructions associated with data to achieve the operations detailed herein. In one example, processor 502 can transform an element or an article (e.g., data, information) from one state or thing to another state or thing.

In at least one embodiment, programmable flash memory 504 and SRAM 512 are configured to store data, information, software, and/or instructions associated with DSP 500, and/or logic configured for programmable flash memory 504 and SRAM 512. For example, any logic described herein can, in various embodiments, be stored for DSP 500 using any combination of programmable flash memory 504 and SRAM 512.

Internal bus 520 can be configured as an interface that enables one or more elements of DSP 500 to communicate in order to exchange information and/or data. Bus 520 can be implemented with any architecture designed for passing control, data and/or information between processors, memory elements/storage, peripheral devices, and/or any other hardware and/or software components that may be configured for DSP 500. In at least one embodiment, bus 520 may be implemented as a fast kernel-hosted interconnect, potentially using shared memory between processes (e.g., logic), which can enable efficient communication paths between the processes.

In various embodiments, the DSP 500 may store data/information in any suitable volatile and/or non-volatile memory item (e.g., magnetic hard disk drive, solid state hard drive, semiconductor storage device, RAM, read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad term ‘memory element’. Data/information being tracked and/or sent to one or more entities as discussed herein could be provided in any database, table, register, list, cache, storage, and/or storage structure: all of which can be referenced at any suitable timeframe. Any such storage options may also be included within the broad term ‘memory element’ as used herein.

Note that in certain example implementations, operations as set forth herein may be implemented by logic encoded in one or more tangible media that is capable of storing instructions and/or digital information and may be inclusive of non-transitory tangible media and/or non-transitory computer readable storage media (e.g., embedded logic provided in: an ASIC, DSP firmware instructions, software [potentially inclusive of object code and source code], etc.) for execution by one or more processor(s), and/or other similar machine, etc. Generally, programmable flash memory 504 and SRAM 512 can store data, software, code, instructions (e.g., processor instructions), logic, parameters, combinations thereof, and/or the like used for operations described herein. This includes programmable flash memory 504 and SRAM 512 being able to store data, software, code, instructions (e.g., processor instructions), logic, parameters, combinations thereof, or the like that are executed to carry out operations in accordance with teachings of the present disclosure.

The ARM/DSP core processor 502 performs the various signal processing functions for the DSP 500 associated with generating chirp pulses, analyzing signals obtained from the digital fuse circuitry and generating ON/OFF control to the digital fuse circuitry, as described herein. In one example, DAC 524-0 is used to output the chirp pulses generated by the DSP 500 onto wire 412 as shown at 450. DAC 524-1 is used to output the ON/OFF control output 422-1 to the FET control circuit 440. The inputs to the DSP 500 from the digital fuse circuitry include the signal (current) after resistor R1, that is provided as input to ADC 522-2. The current into resistor R1 is obtained and provided as input to ADC 522-1. Finally, the current at the input of diode D1 before resistor R4 is provided as input to ADC 522-1, and this current is used to measure impedance on the send wire 412 based on analysis at the frequencies of the chirp pulse. In addition to measuring currents, the DSP uses the signals obtained by ADC 522-0 and ADC 522-1 to measure voltage.

It is to be noted that FIG. 4B shows only one DSP associated with the send wire 412, e.g., DSP 420-1 of FIG. 4A. A similar DSP and connections would be provided for DSP 420-2 of FIG. 4A. However, it is also envisioned that one DSP, with suitable processing capabilities and number of ADCs and DACs could be used in place of two separate DSPs.

Reference is now made to FIG. 4C, which shows a voltage waveform (e.g., DC voltage power) 540. At 542, a start-up mode is initiated at a low voltage, and then the power is increased to an operating voltage level (e.g., 380 VDC, 760 VDC, etc.) as shown at 544. Chirp pulses are continuously applied to the wire on top of the voltage waveform as shown at reference numeral 546. Each chirp pulse 546 (comprising a plurality of frequencies) is represented by a full cycle (360 degrees) of a sine wave shown in FIG. 4C. Voltage is continuously applied while chirp pulses 546 are repeatedly applied on the wire on top of the voltage. There is no need for pulsing power on and off and doing fault detection analysis between pulses. At some point in time, analysis of the reflected signal on the wire indicates an impedance-based fault and the voltage on the wire is shut off (e.g., via FETs) as shown at 550. At 552, the restart mode may be re-initiated and power may be turned back on to the full operating voltage level as shown at 554. Had no impedance-based fault been detected, then the voltage would have been kept on as shown at reference numeral 556.

The frequencies of each of the chirp pulses could be in any order, such as decreasing order (from highest frequency to lowest frequency). As explained herein, in most applications, a series of chirp pulses will be applied on a continuous/repeating basis. A reflected signal is received and the reflected signal could potentially be impacted by an impedance, e.g., a body impedance of a human touching the line (with one or both hands).

The input signal contains frequency components corresponding to the frequency components of the chirp pulse that are impacted by an impedance (e.g., a body impedance if a human body is in contact across one of the wires of the cable). The body impedance model may be represented by the equation:

$$BI ( x ) = {\sum }_{i}^{N} sin ( i ) ( R i + j X i m ,$$

where Xm is mostly capacitive in nature but does have an inductive component.

Each frequency is analyzed to look for an indication of impedance impact. Each frequency can have a different loss impact.

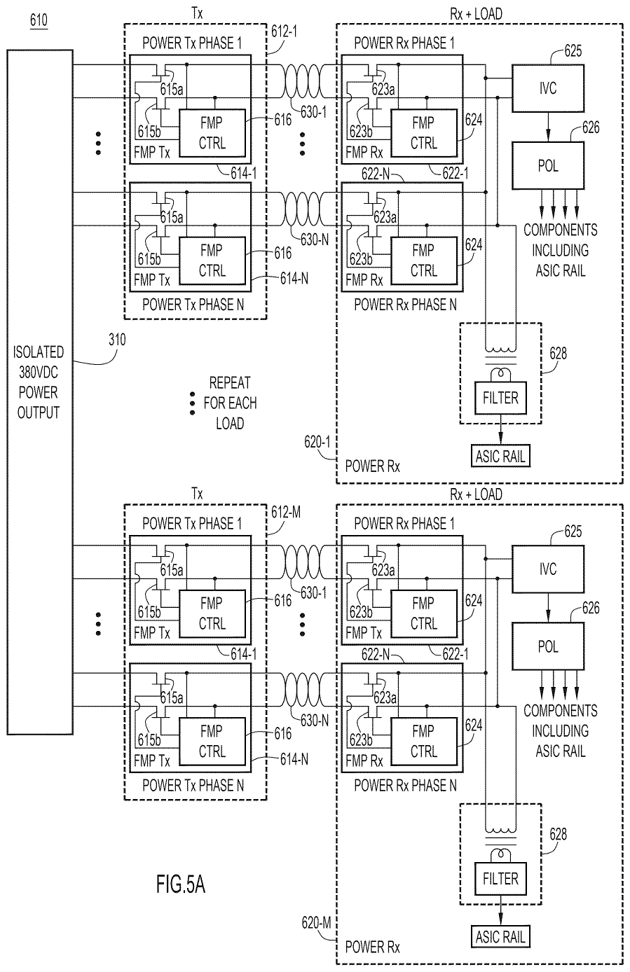

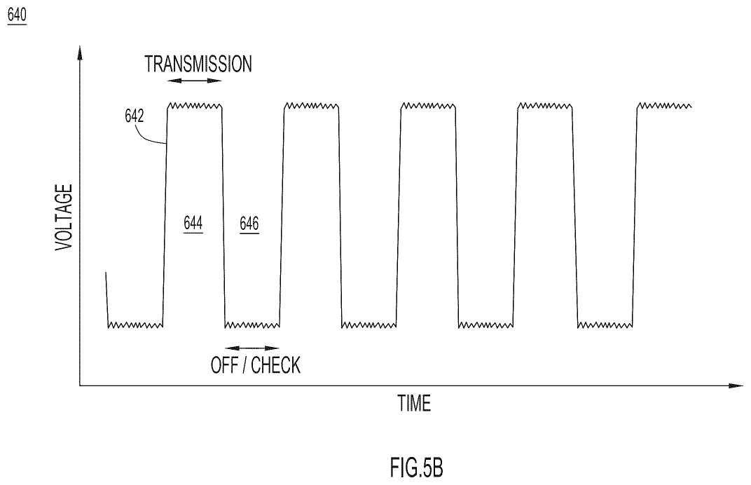

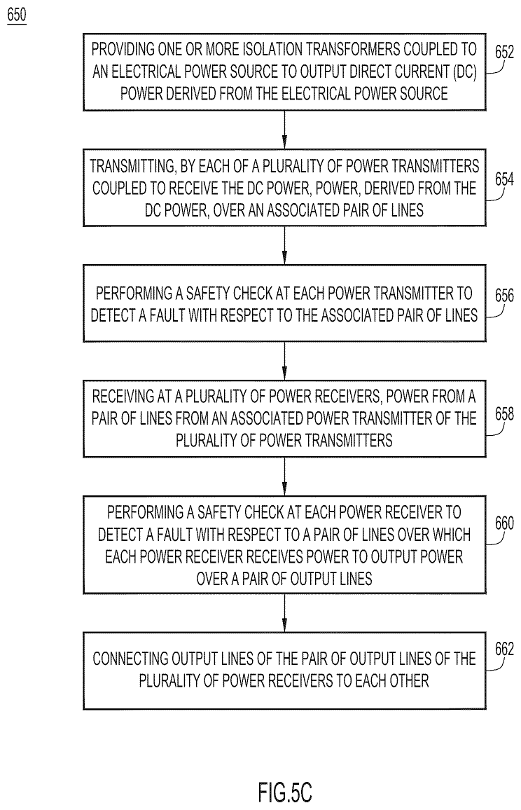

Reference is now made to FIGS. 5A and 5B for a description of a power distribution system in which fault detection is made using power pulsing techniques. FIG. 5A shows a block diagram of a power distribution system 600 that includes, in this example, an isolated (380 Volts DC (VDC)) power source 610, a plurality of power transmitters 612-1 to 612-M, each comprising N FMP transmitters 614-1 to 614-N to output N phases of power. Each FMP transmitter 614-1 to 614-N includes FET switches 615a and 615b and an FMP controller (CTRL) 616. The FMP CTRL 616 controls the FET switches 615a and 615b connected to power lines for a given phase to connect/disconnect the DC power from being transmitted at its output when the FMP CTRL 616 detects a fault. The operations of the FMP CTRL 616 are described below in connection with FIG. 5B.

The power distribution system 600 further includes a plurality of power receivers 620-1 to 620-M, each associated with a given load, and comprising a plurality of FMP receivers 622-1 to 622-N for each of the N phases of power from the N FMP transmitters of a power transmitter. Each FMP receiver 622-1 to 622-N is coupled by N cables/wire pairs 630-1 to 630-N to a corresponding FMP transmitter for the associated phase. Each FMP receiver 622-1 to 622-N includes a pair of FET switches 623a and 623b and an FMP CTRL 624 connected to the FET switches 623a and 623b for that phase. In addition, each power receiver 620-1 to 620-M includes an integrated voltage controller (IVC) 625 connected to a point-of-load (POL) 626 that is configured to provide power supply voltage to one or more components, such as a rail voltage for an application integrated circuit (ASIC). Further still, each power receiver 620-1 to 620-M may include transformer and filter circuitry 628, similar to that shown in FIG. 2, to output an ASIC rail voltage. The arrangement of the power distribution system 600 allows for direct path power delivery with better efficiency to higher power components, such as ASICs, network processor units (NPUs) and graphical processor units (GPUs).

FIG. 5B illustrates a diagram 640 generally depicting operation of the FMP CTRLs shown at the transmit side and receive side of the power distribution system 600 in FIG. 5A. Further details of the FMP CTRLs may be found in commonly assigned U.S. Pat. Nos. 10,958,471; 11,683,190; 12,052,112; 11,456,883; 11,637,497; 10,735,105, 10,790,997, 11,063,630; 11,258,520; 11,916,374; 11,923,678; and 12,061,506. Each power transmitter generates and sends a power waveform 642 that comprises a sequence of pulses that switch between an “on” state 644 and an “off” state 646. The relative length/duration of the “on” and “off” states, referred to as duty cycle, may vary and FIG. 5B is not meant to be at scale. During the off states 646, fault detection analysis may be performed to determine whether the voltage or current conditions on a wire is indicative of a fault that should warrant shutting down the power, by disconnecting the pairs of FETs. Examples of various techniques to detect faults during the off periods are described in the aforementioned patents and patent applications.

FIG. 5C is a flow chart depicting a method 650 according to an example embodiment. At 652, the method includes providing one or more isolation transformers coupled to an electrical power source to output Direct Current (DC) power derived from the electrical power source. At 654, the method includes transmitting, by each of a plurality of power transmitters coupled to receive the DC power, power, derived from the DC power, over an associated pair of lines. At 656, the method includes performing a safety check at each power transmitter to detect a fault with respect to the associated pair of lines. At 658, the method includes receiving at a plurality of power receivers, power from a pair of lines from an associated power transmitter of the plurality of power transmitters. At 660, the method includes performing a safety check at each power receiver to detect a fault with respect to a pair of lines over which each power receiver receives power to output power over a pair of output lines. At 662, the method includes connecting output lines of the pair of output lines of the plurality of power receivers to each other.

### FMP Bus Bar and Related Arrangements

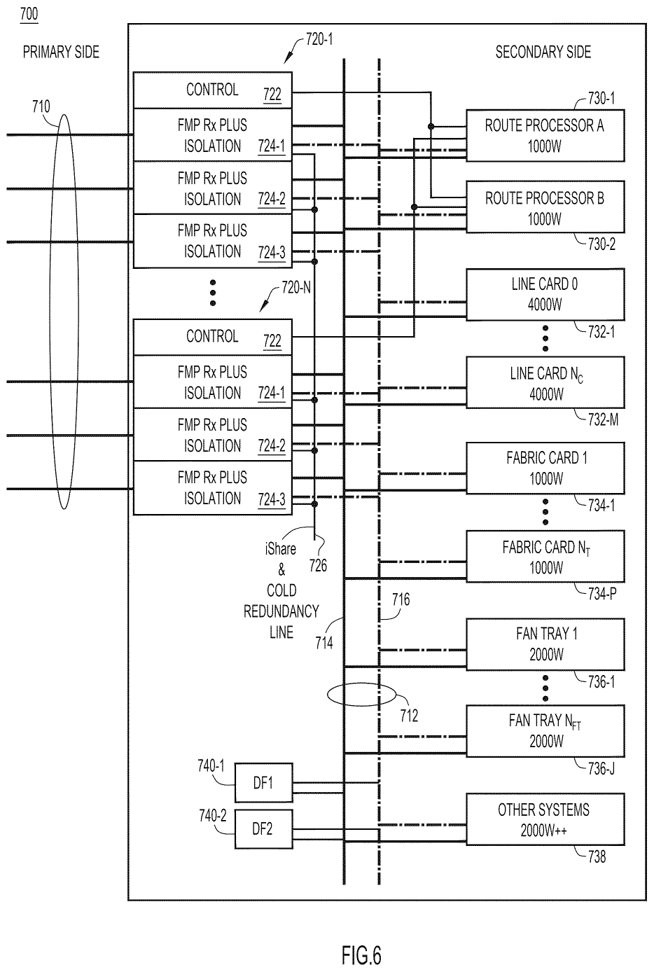

Turning now to FIG. 6, a block diagram is shown of a power distribution system 700 that may be particularly configured to be deployed in a confined space, housing or “box” (chassis), such as a 19-inch rack. For simplicity, the diagram of FIG. 6 does not show the power supply units (PSUs) that provide AC power, DC power or FMP power, with DC-DC isolation, but they are connected by a cable 710 to the power distribution system 700.

The power distribution system 700 includes a regulated bus bar (or power distribution network) 712 that includes a data bus 714 and a power bus 716. In some instances, the bus bar 712 may just include a power bus 716 (and not the data bus 714). A plurality of power receiver blocks 720-1 to 720-N connect to the bus bar 712. Each power receiver block includes a controller 722, several FMP receivers (plus isolation circuitry) 724-1, 724-2 and 724-3, each of which is connected to wires of the cable 710. There is a current share bus (i-Share) and cold redundancy line 726 connected to each of the FMP receivers in the power receiver blocks 720-1 to 720-N.

The power distribution system 700 further includes a plurality of power consuming devices that use the power provided to the bus bar 712 by the power receiver blocks 720-1 to 720-N. For example, on the power consuming “secondary” side of the bus bar 712 there are a route processor (router) 730-1, a route processor 730-2, line cards 732-1 to 732-M, fabric cards 734-1 to 734-P, fan trays 736-1 to 736-J, and other systems/components 738.

The FMP receivers (724-1, 724-2 and 724-3) in the power receiver blocks 720-1 to 720-N may be configured to detect faults and disconnect power to the bus bar 712 when they detect a fault. In addition, or in the alternative, the power distribution system 700 may include digital fuse processors, shown as DF1 at reference numeral 740-1 and DF2 at reference numeral 740-2, that connect to the bus bar 712 and provide fault detection capabilities on the bus bar 712. Some concerns with internal or secondary side power distribution are human safety as well as arc flashes.

The FMP receivers may be deployed in multiple power shelves in a chassis or rack. The bus bar 712 is a regulated bus because the power delivered to it is regulated voltage, for example, 380 VDC. Fault managed power techniques may be deployed on the bus bar 712 to detect for faults and shut off power in the event of a detected fault. To this end, in one embodiment, one or several (for redundancy) digital fuse fault detectors are provided as part of the system 700. For example, FIG. 6 shows two digital fuse fault detectors, DF1 and DF2 at reference numerals 740-1 and 740-2, respectively. DF1 740-1 and DF2 740-2 are configured to monitor current and voltage on the bus bar 712 to detect when a fault condition is present on the bus bar 712, such as a human touch fault. Though not specifically shown as such in FIG. 6, it is to be understood that when multiple digital fuse fault detectors are employed, each may be connected to different portions/areas/locations of the bus bar 712.

Thus, at a high level, FIG. 6 depicts a system that includes a bus bar that supports communication of power; a plurality of power receivers coupled to the bus bar, each power receiver configured receive a supplied power and to provide an output power to the bus bar, each power receiver further configured to detect a fault in the output power provided to the bus bar; and one or more power consuming devices connected to the bus bar and configured to receive and consume power provided by a power receiver of the plurality of power receivers. In some instances, there are a plurality of power transmitters connecting to the bus bar that are configured to provide power to the plurality of power receivers, and the plurality of power transmitters are each configured to detect a fault in output power provided to the bus bar.

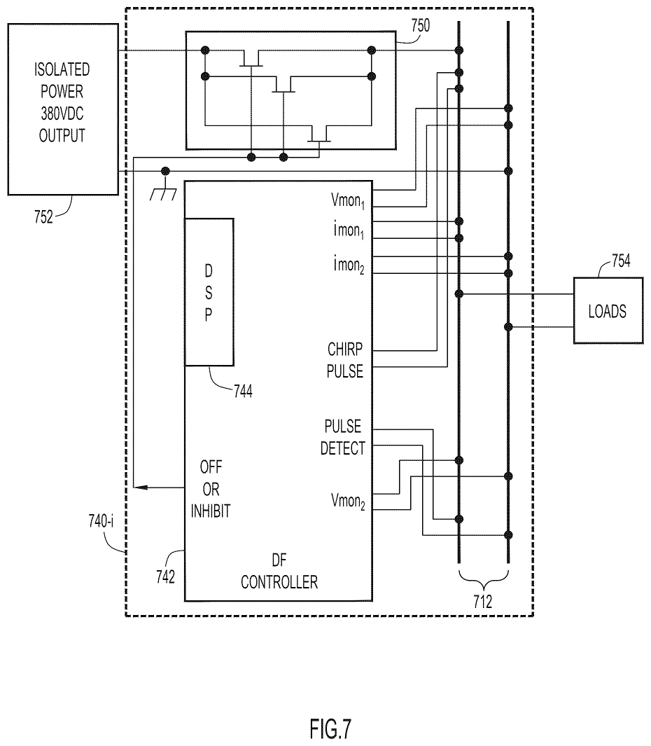

Turning now to FIG. 7, a more detailed diagram is provided to illustrate how a digital fuse fault detector, e.g., DF1 and DF2, are connected to a bus bar (such as a 380 V bus bar) and configured to detect a fault. FIG. 7 shows a digital fuse fault detector 740-i that is representative of DF1 and DF2 shown in FIG. 6. More details of the digital fuse fault detector are described above in connection with FIGS. 4A, 4B and 4C. The digital fuse fault detector 740-i includes a DF controller 742 that includes a DSP 744, as described above in connection with FIGS. 4A and 4B. A FET switch array 750 is provided that connects between the bus bar 712 and an isolated power shown generally at reference numeral 752 (though the isolated power may be an output from one of the FMP receiver blocks shown in FIG. 6). The FET switch array 750 is controlled by an Off or Inhibit output of the DF controller 742. Power is provided from the bus bar 712 to various power consuming devices that are generally represented as loads 754.

The DF controller 742 generates chirp pulses that are applied to the bus bar 712 at one location, and monitors current (imon₁, imon₂) and voltage (Vmon₁, Vmon₂) on the bus bar 712 as a result of the chirp pulses at other locations. The DSP 744 analyzes these voltage and current signals to detect whether there is an impedance-based fault using the techniques described above in connection with FIGS. 4A-4C. When the DSP 744 detects a fault, the Off or Inhibit output is set to the FET switch array 750, causing the FET switch array 750 to disconnect the DC power 752 from the bus bar 712. The digital fuse fault detection techniques may be used to safely distribute DC power in multi-phase, single phase and/or multi-drop configurations. This allows for minimizing the size of the bus bar 712 due to the level of the DC voltage employed (380 VDC, for example), and facilitates a small form factor implementation. The loads 754 may have a step-up transformer, step-down transformer or IVC arrangement, similar to that described above in connection with FIG. 3.

The pulse power fault detection techniques as described above in connection with FIGS. 5A and 5B may be employed in the power distribution system 700 shown in FIG. 6. In such an implementation, it may be desirable to using a higher frequency power pulse waveform and end terminate it into a receiver with an integrated direct-attach transformer for local powering of an ASIC, for example.

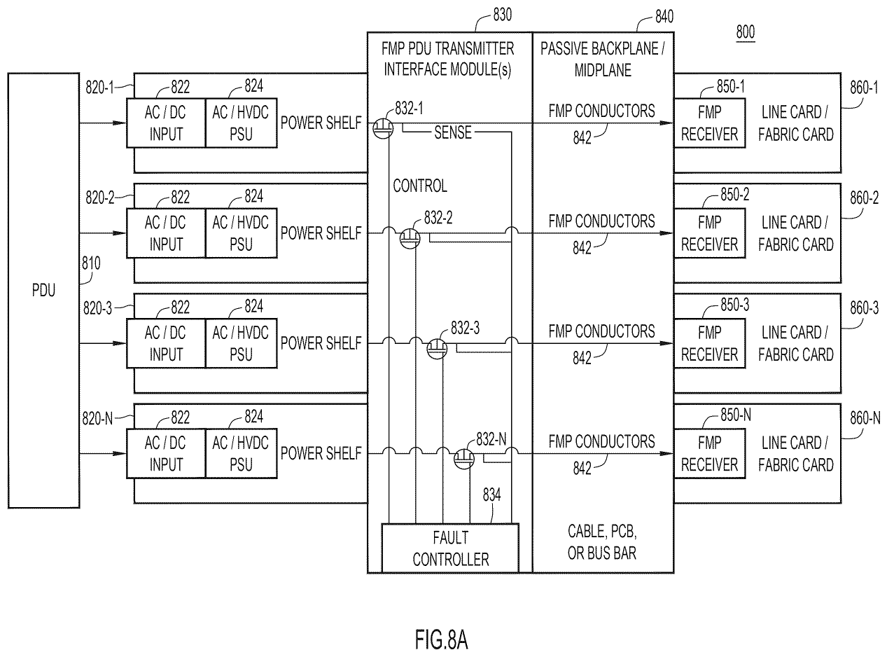

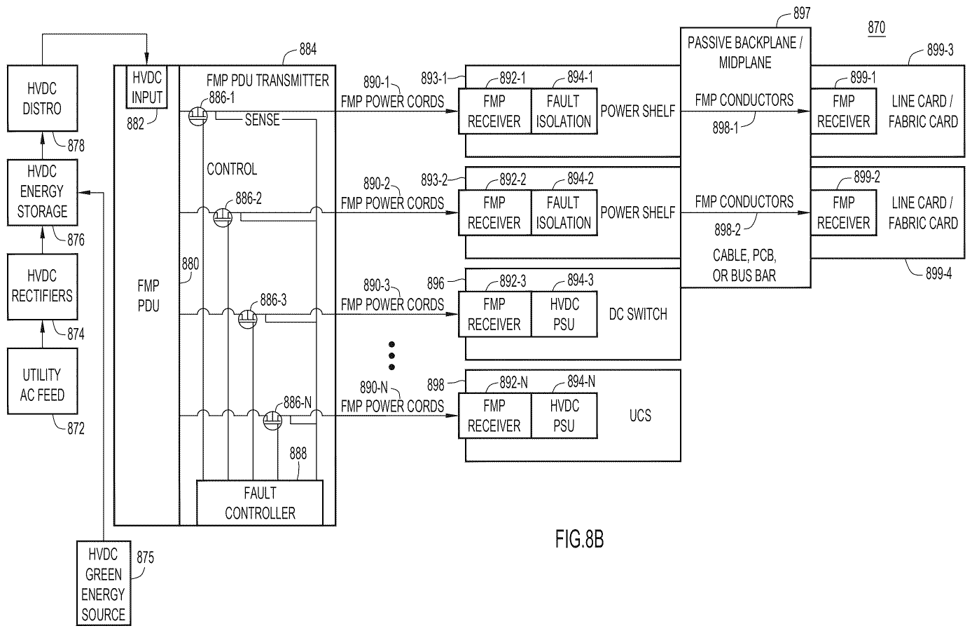

Reference is now made to FIG. 8A, which shows a block diagram of an FMP power distribution system 800 in a modular chassis arrangement. The power distribution system 800 includes a power distribution unit (PDU) 810 that provides input power to power supply units (PSUs) on power shelves. In particular, each of a plurality of power shelves 820-1, 820-2, 820-3, . . . , 820-N includes an AC/DC input 822 and an AC/HVDC (high voltage DC) PSU 824. Each power shelf provides AC or DC power to an FMP backplane interface module 830 (or multiple modules). The FMP backplane interface module 830 includes FET switches 832-1, 832-2, 832-3, . . . , 832-N, one for each power shelf, to pass or inhibit power. A fault controller 834 is coupled to the FET switches 832-1 to 832-N. The fault controller 834 obtains current/voltage sense measurements from lines that carry power through the FMP backplane interface module 830 and analyzes those measurements (using the fault detection techniques described herein or other fault detection techniques) and controls the FET switches 832-1 to 832-N to open if a fault is detected on a respective line. The fault controller 834 performs detection of faults such as human touch faults, arc faults, ground faults, overcurrent faults and undervoltage sense faults.

The FMP backplane interface module 830 is coupled to a passive backplane/midplane 840 that comprises conductors/wires (in the form of cables, PCB or bus bar) 842 carrying power from respective lines of the FMP backplane interface module 830 to an associated FMP receiver of a plurality of FMP receivers 850-1, 850-2, 850-3, . . . , 850-N associated with (or part of) a line card or fabric card 860-1, 860-2, 860-3, . . . , 860-N.

In the system arrangement of FIG. 8A, heavier bus bars can be replaced with cables (providing for higher voltage and thus lower current). In addition, the power distribution system 800 includes fault and surgent protection, at the individual line level. There is no or little risk of carbonization events in this arrangement and it can be easily adapted for any input power and output power.

Turning now to FIG. 8B, a datacenter power distribution system 870 is shown that is configured to support fault managed power capabilities. The datacenter power distribution system 870 includes a utility AC feed 872, HVDC rectifiers 874, HVDC green (e.g., solar) energy source 875, HVDC energy storage 876 and HVDC distribution unit 878. An FMP PDU 880 has an HVDC input 882 that receives the HVDC power from the HVDC distribution unit 878. The FMP PDU 880 further includes an FMP transmitter 884 that in turn includes FET switches 886-1, 886-2, 886-3, . . . , 886-N, one for each of multiple power lines, to pass or inhibit power onto one of the multiple power lines. A fault controller 888 is coupled to the FET switches 886-1 to 886-N. The fault controller 888 obtains current/voltage sense measurements from lines that carry power and analyzes those measurements (using the fault detection techniques described herein or other fault detection techniques) and controls the FET switches 886-1 to 886-N to open if a fault is detected on a respective line. The fault controller 888 performs detection of faults such as human touch faults, arc faults, ground faults, overcurrent faults and undervoltage sense faults.

The FMP transmitter 884 outputs power over FMP power cords/cables 890-1, 890-2, 890-3, . . . , 890-N to FMP power receivers 892-1 to 892-N. In one example, FMP power receiver 892-1 is associated with a power shelf 893-1 that includes fault isolation block 894-1, and similarly FMP power receiver 892-2 is associated with a power shelf 893-2 that includes fault isolation block 894-2. In a further example, FMP power receiver 892-3 is associated with HVDC PSU 894-3 to provide power for a data center (DC) switch 896. Similarly, FMP power receiver 892-N is associated with HVDC PSU 894-N for a unified computing system (UCS) 898. The fault isolation blocks 894-1 and 894-2 may perform fault detection and isolation from power when a fault is detected using any one or more of the digital fuse or pulse power (voltage or current) fault detection techniques described herein.

The power shelves 893-1 and 893-2 are connected to a passive backplane/midplane 897 that includes FMP conductors 898-1 and 898-2 (in the form of cables, PCB or bus bar) to carry power to FMP power receivers 899-1 and 899-2 associated with or integrated into a line card/fabric card 899-3 and 899-4, respectively.

Artificial intelligence (AI) is expected to drive an order of magnitude increase in rack power density in datacenters. Locating the FMP protection upstream in the datacenter, as shown in FIG. 8B, enables moving from 208V AC to 400V DC for a significant increase in power delivered while increasing safety and efficiency.

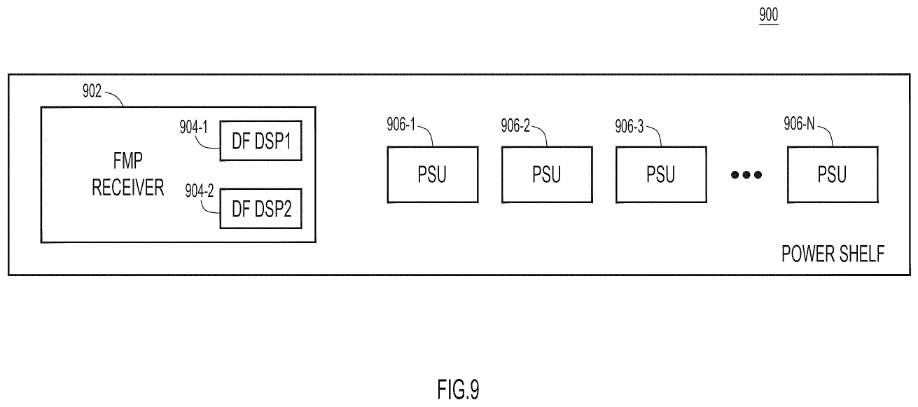

FIG. 9 illustrates a diagram of a power shelf 900 that may be used in the various power distribution systems described herein, such as in FIGS. 8A and 8B. The power shelf 900 includes an FMP power receiver 902 having associated or integrated therewith redundant digital fuse controllers DF DSP1 and DF DSP2, shown at reference numerals 904-1 and 904-2. The FMP power receiver 902 provides fault-protected power to a plurality of PSUs 906-1, 906-2, 906-3, . . . , 906-N.

### Current Share (“i-Share”) and Cold Redundancy Applied to FMP

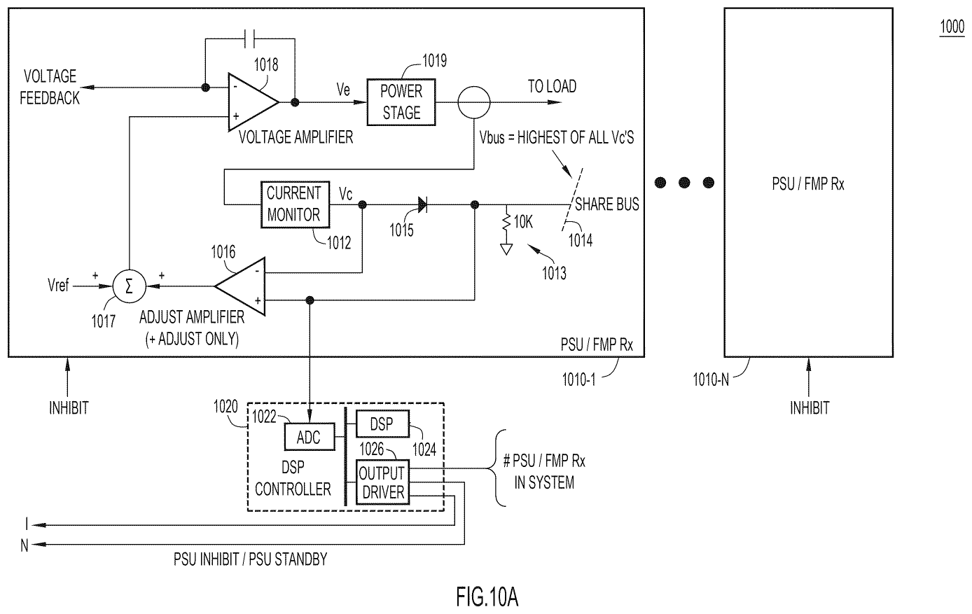

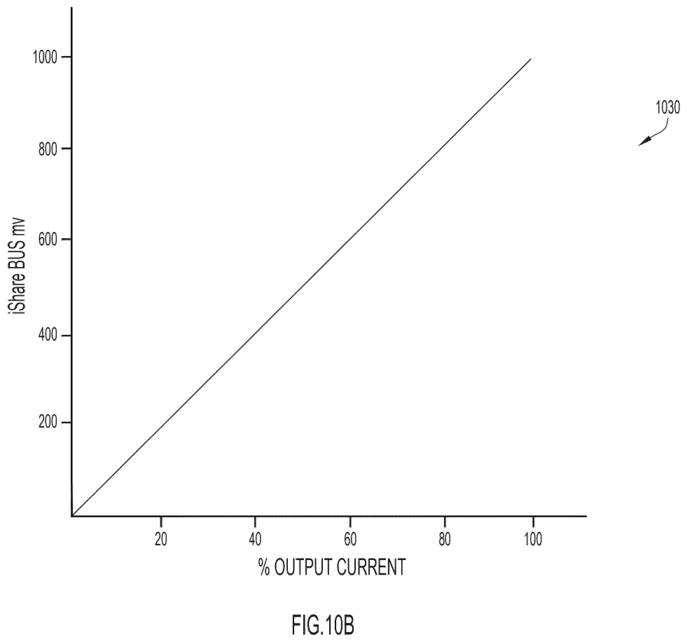

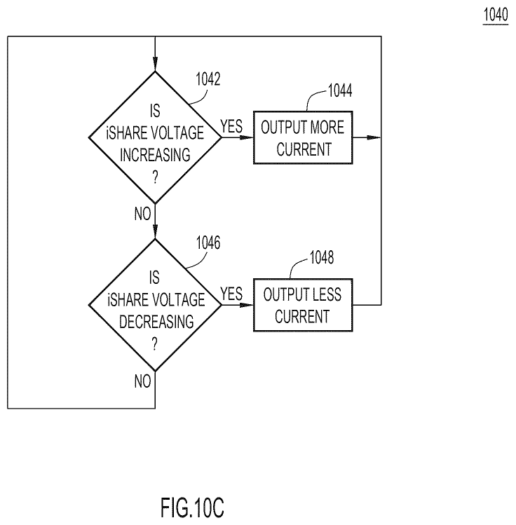

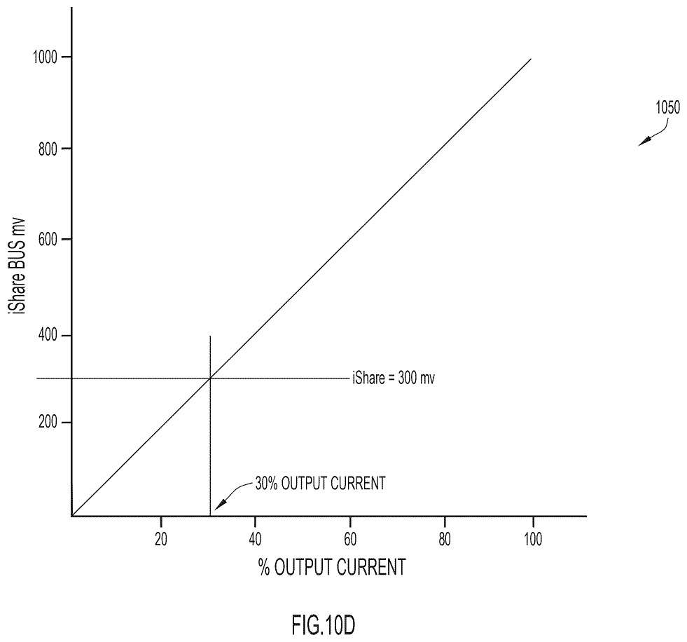

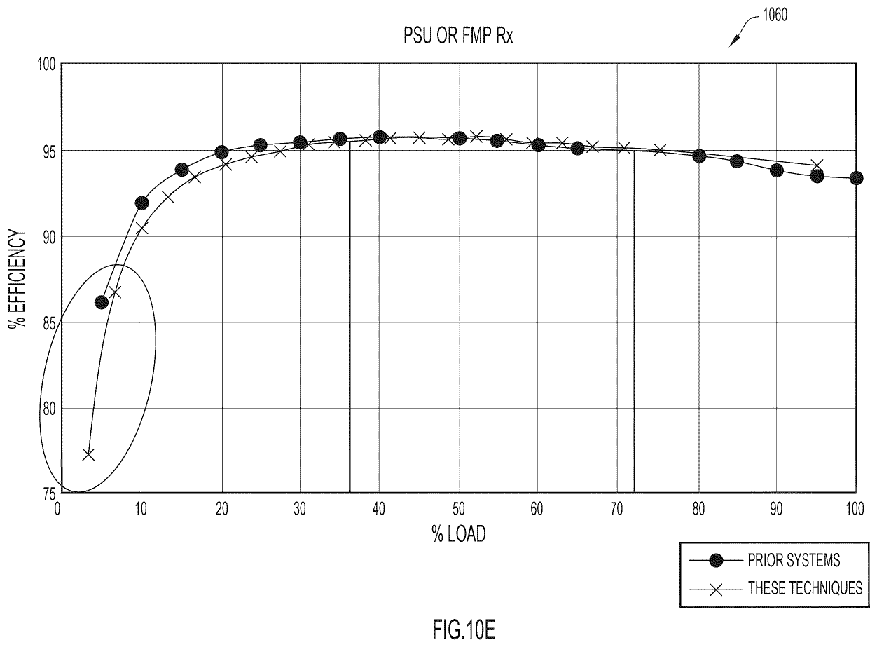

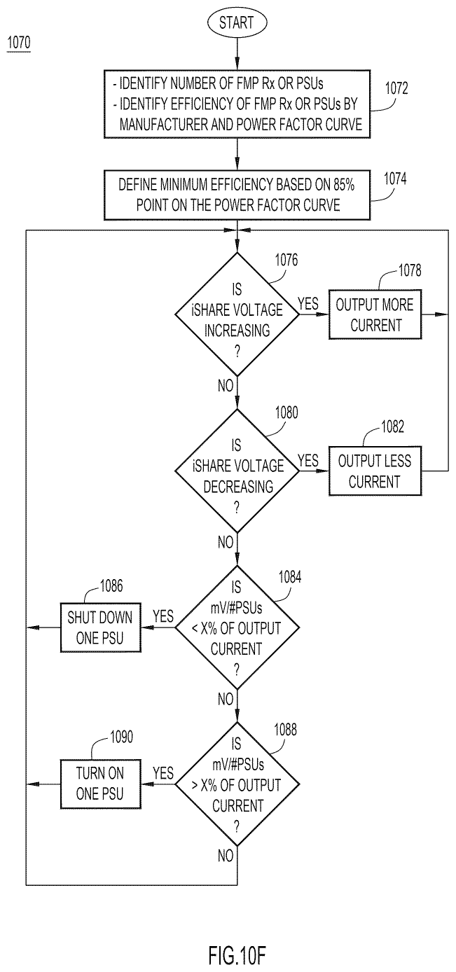

Reference is now made to FIGS. 10A-10F for a description of how a current share bus, also called “iShare”, is used in connection with fault managed power techniques. FIG. 10A shows a receive side of a power system 1000 that includes a plurality of PSUs 1010-1 to 1010-N and a DSP controller 1020 that may take the form of a single DSP chip or field programmable gate array (FPGA) that may reside in a power shelf with the PSUs (or FMP power receivers) 1010-1 to 1010-N. Each PSU 1010-1 to 1010-N is configured to support current share techniques and provide a current measurement onto a current share bus called “Share Bus”. Specifically, as shown for PSU 1010-1, a current monitor 1012 outputs a voltage Vc that is a measure of current provided to a load, and this current measurement is provided to the Share Bus 1014. The diode 1015 prevents current from backflowing into the PSU from the Share Bus 1014. Each PSU dumps onto the Share Bus 1014 this voltage measurement, Vc. A PSU is looking at what the highest voltage measurement is on the Share Bus and that feeds into the adjust amplifier 1016 which uses that, and the local voltage measurement Vc to output an adjustment that is then added to a reference voltage Vref by a summer 1017, which in turn is connected to the voltage amplifier 1018 to adjust the output voltage Ve into the power stage 1019 that supplies current to the load. The 10k Ohm resistor provides stability to the Share Bus 1014. It should be understood that a typical implementation will have two DSP controllers 1020, for redundancy.

The DSP controller 1020 taps onto the Share Bus 1014, via the 10k resistor 1013. The DSP controller 1020 includes an analog-to-digital converter (ADC) 1022, a DSP 1024 and an output driver 1026. The DSP controller 1020 receives a configuration input as to the number of PSUs or FMP receivers in the system, which may come from a PSU identifier (ID) pin or system software. The DSP controller 1020 thus knows which PSU is in which slot (in a rack/power shelf) and knows whether it is active or not and knows how many PSUs are in the system. There is an Inhibit control line to each PSU 1010-1 that allows the DSP controller to shut off the power output by a given PSU. In some applications, the Inhibit control line may shut down the entire power supply, including the output.

Reference is now made to FIG. 10B and FIG. 10C. The DSP controller 1020 knows the highest voltage reported on the Share Bus (iShare bus), and thus knows the percent output current from each PSU. For example, if, as shown by the curve 1030 in FIG. 10B, the DSP controller 1020 reads 400 millivolts (mV) on the Share Bus, this means that each PSU is outputting 40% of its total capacity. Thus, as shown by the DSP loop 1040 of FIG. 10C, if, at 1042, the iShare voltage is increasing, then at 1044, the PSU needs to push more current to its output. If, at 1046, the iShare voltage is decreasing, then the PSU needs to output less current at 1048, and this loop repeats until all PSUs reach an equilibrium, and the output current then settles.

With reference to FIGS. 10D and 10E, a specific example is described. There are three PSUs (or FMP receivers) in this example. If the DSP controller measures 300 mV (as the highest measured voltage reported on the Share Bus), this indicates, according to the curve 1050, that each PSU is outputting current at 30% of its load.

As shown by the percent efficiency versus percent load curve 1060 in FIG. 10E, at 30% load, no matter what is done in terms of shutting off a PSU, the system is already at near peak efficiency, so at this point, it is better to leave all three PSUs on and providing output current. However, if the DSP controller measures 50 mV, this indicates that each PSU is operating at 5% of its load. According to the curve shown in FIG. 10E, 5% percent of the load translates to a low % efficiency (less than 80%). If the DSP controller were to shut off/inhibit 2 PSUs/FMP Rx's, this moves the % load up to approximately 15%, which increases the efficiency to close to peak efficiency (nearly 95%). Thus, by using only one PSU, a much-improved power efficiency can be achieved.

An FMP transmitter and an FMP receiver each has a curve that may not be identical to that shown in FIG. 10E, is nevertheless somewhat similar. Thus, these iShare control techniques may be employed to greatly improve the efficiency of the system, on both the transmit side and the receive side.

FIG. 10F illustrates a flow chart that depicts a logic flow for a control loop 1070 to control a plurality of PSUs/FMP Rx's using the principles of iShare and cold redundancy described above in connection with FIGS. 10A-10E. The control loop 1070 involves, at step 1072, identifying/determining the number of FMP receivers (Rx's)/PSUs in the system and also identifying/determining an efficiency of the FMP Rx's/PSUs by manufacturer efficiency or a power factor curve derived for the FMP Rx's/PSUs. At step 1074, a minimum efficiency is defined based on, for example, an 85% point on a power factor curve. At step 1076, the controller determines whether the iShare voltage is increasing. If so, then at step 1078, the PSU is controlled to output more current. At 1080, the controller determines whether the iShare voltage is decreasing. If so, then at step 1082, the PSU is controlled to output less current.

At step 1084, the controller determines whether the ratio of millivolts (mV) to the number of PSUs is less than a predetermined percentage (X %) of the output current. If so, then at 1086, the controller shuts down one PSU. Next, at step 1088, the controller determines whether the ratio of mV to the number of PSUs is greater than the predetermined percentage (X %) of the output current. If so, then the controller turns on one PSU.

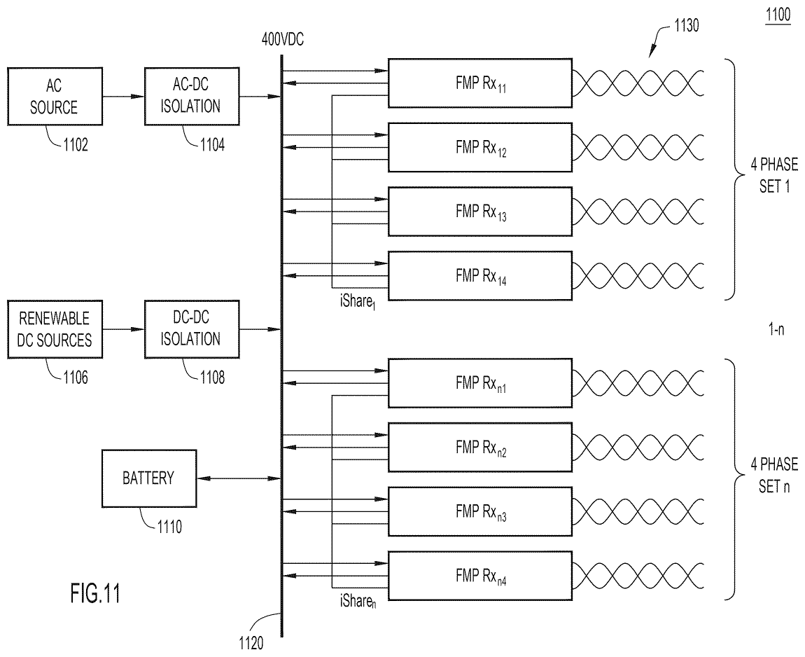

Turning now to FIG. 11, a diagram is shown of a portion of a power distribution system 1100 that resides in an electrical room, for example. There is an AC source 1102 and AC-DC isolation blocks 1104, as well as renewable DC sources 1106 and DC-DC isolation blocks 1108. One or more batteries 1110 may also be provided. The output of the AC-DC isolation block 1104, DC-DC isolation block 1108 and battery 1110 are coupled to a bus bar 1120, e.g., a 400 VDC bus bar. Also connected to the bus bar 1120 are a plurality of FMP transmitters for a plurality of phases, and denoted FMP Tx₁₁ to FMP Tx₁₄ for Set 1 to FMP TXₙ₁ to FMP Txₙ₄ for Set N. For example, which are N sets of FMP transmitters, each set including an FMP transmitter for each of four phases. Each of the FMP transmitters is connected to an associated cable 1130. Each of the FMP transmitters are bi-directional and are thus capable of being configured to operate as FMP receivers to receive power from the bus bar 1120 and transmitting power to the bus bar 1120, and likewise receive power via cable 1130 and transmit power to cable 1130. When a set of FMP transmitter phases is set to receive mode, the iShare techniques described above in connection with FIGS. 10A-10F may be used to auto-balance the load sharing on the cables for a given set of FMP transmitters (that are now configured to operate as FMP receivers). Separate load sharing buses may be used between the phase groups.

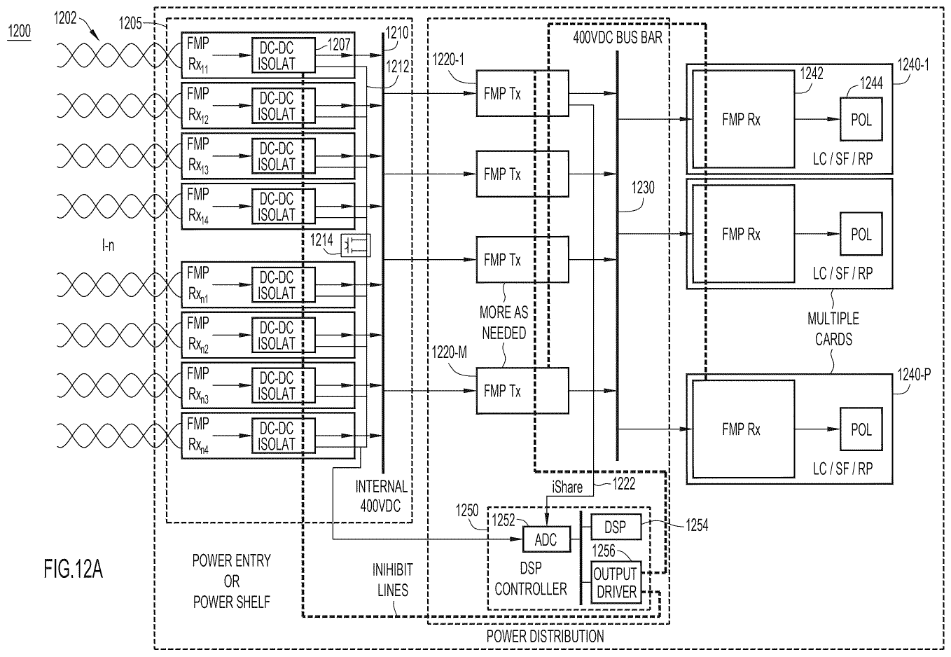

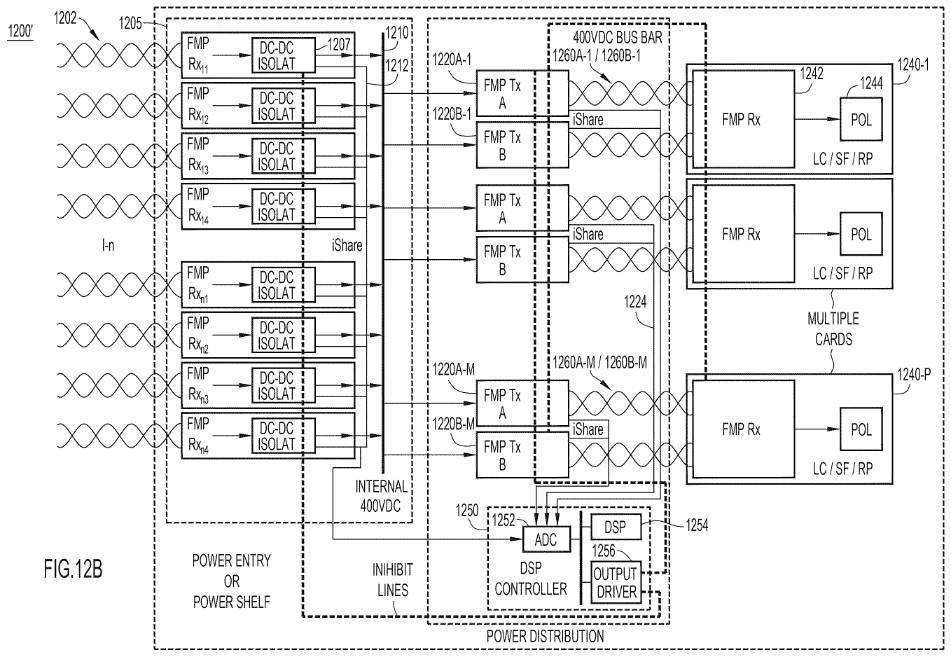

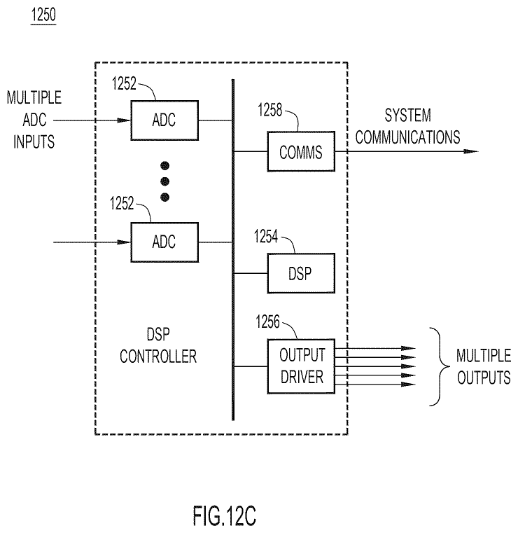

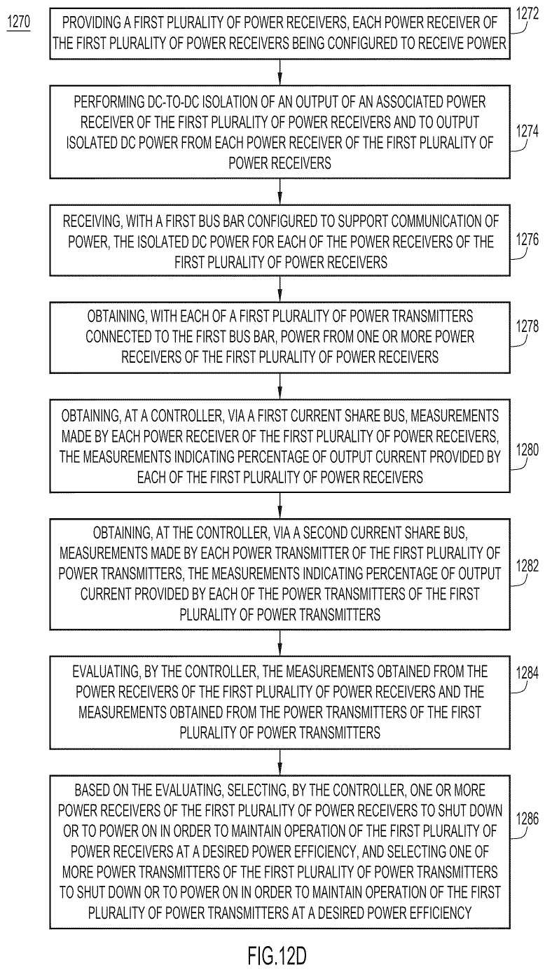

Referring now to FIG. 12A, a diagram is shown of a power distribution system 1200 that resides in a power entry or power shelf of a rack. The input to the system 1200 is over cables 1202 from the sets of FMP transmitters shown in FIG. 11, for example. Thus, the system 1200 comprises an FMP receiver block 1205 comprising multiple sets of FMP receivers, with each set having four phases, as one example, and denoted as FMP Rx₁₁ to FMP Rx₁₄ for Set 1 to FMP Rxₙ₁ to FMP Rxₙ₄ for Set N. There are DC-DC isolation blocks 1207 at the output of each FMP receiver to output power to a bus bar 1210. FIG. 12A shows that a current bus 1212 (iShare) is shared across all of the FMP receivers (across all N sets), but it is also envisioned that iShare is selectively performed only within each set to balance current across all 4 phases within a set, using a FET switch 1214 to segment iShare into smaller more granular portions for FMP Rx/Tx shut down, as shown. However, by having iShare across all of the FMP receivers (across all N sets), power can be balanced across all of the FMP receivers.

There are a plurality of FMP transmitters 1220-1 to 1220-M that receive power from the bus bar 1210 and transmit it to another bus bar 1230. Further, there are a plurality of line cards (LCs)/switch fabrics (SFs)/route processors (RPs) 1240-1 to 1240-P connected to the bus bar 1230, each of which includes an FMP receiver 1242 and a point of load (POL) 1244. The FMP transmitters 1220-1 to 1220-M are configured to support a current share bus 1222 (iShare) and there is a DSP controller 1250 (similar to the DSP controller shown in FIG. 10A) that performs the current balancing operations described above in connection with FIGS. 10A-10F, among the FMP receivers as well as the FMP transmitters via current share bus 1212 and current share bus 1222. The DSP controller 1250 includes an analog-to-digital converter (ADC) 1252, a DSP 1254 and an output driver 1256. The DSP controller 1250 is configured to inhibit any of the FMP transmitters 1220-1 to 1220-M to achieve equal current draw across FMP cabling, as well as to inhibit any of the FMP receivers to achieve desired efficiency and equal current share. Said another way, the DPS controller 1250 can perform the efficiency adjustment techniques of FIGS. 10A-10F at the overall system level (across FMP transmitters and FMP receivers). Data representing the power efficiency curve at the FMP transmitter/FMP receiver level can be loaded into the DSP controller 1250 which then has a system-wide view of the efficiency characteristics and can turn on/off FMP transmitters/FMP receivers to achieve a desired efficiency and desired power savings. There may be two DSP controllers 1250 for redundancy.

FIG. 12B illustrates a diagram of a power distribution system 1200′ that is a variation of the power distribution system 1200. In particular, in power distribution system 1200′, the FMP transmitters 1220-1 to 1220-M are replaced with redundant (“A” and “B”) FMP transmitters 1220A-1/1220-B-1 to 1220A-M/1220-B-M, and the bus bar 1230 is replaced with cables 1260A-1/1260B-1 to 1260A-M/1260B-M. Moreover, cable pairs connect between a redundant FMP transmitter pair and a corresponding LC/SF/RP 1240-1 to 1240-P, as shown in FIG. 12B. In addition, FMP transmitters within each redundant A/B pair are configured with iShare capabilities to a current bus 1224 (for each redundant pair of FMP transmitters) and controlled by the DSP controller 1250.

The FMP and iShare concepts depicted in FIGS. 12A and 12B may apply to a network router or switch, as well as to artificial intelligence (AI) systems where the LC/SF/RP is an AI processor.

Furthermore, the iShare concepts may be configured to select/prioritize use of FMP transmitters/FMP receivers based on power source, and not just based on the efficiency curve. For example, some power channels may be sourced from a local solar power source and other power channels are sourced from utility power sources. It may be desirable to prefer the “green” solar power-driven FMP transmitter/FMP receiver channels over the utility driven power channels. This is different from existing/conventional analog iShare techniques that only are for sharing power output from power supplies equally according to their fraction of the overall power. The techniques presented herein allow for breaking up the iShare bus into different pools, and then using DSP control monitoring of it to provide a two-way control loop where the DSP controller imposes the power supply/FMP transmitter selection to force power (current) to come from a preferred source. One solution/use case may involve a power converter bank (particularly on the AC-to-DC side) with different capacities to build up the appropriate combination of power capacity for a given period of time.

FIG. 12C shows a block diagram of DSP controller 1250 expanded to support the power distribution systems 1200 and 1200′ depicted in FIGS. 12A and 12B. The DSP controller 1250 can accept multiple inputs and provide multiple outputs to control (shut off/turn on) the various FMP transmitters and FMP receivers in the power distribution systems 1200 and 1200′. To this end, the DSP controller 1250 may include multiple instances of ADCs 1252, a DSP 1254, an output driver 1256 to provide multiple outputs, and a communications (comms) interface 1258 to support system communications.

The DSP controller 1250 may perform a control loop similar to that shown in FIG. 10F, except that at step 1086, the DSP controller 1250 may shut down the most inefficient FMP transmitter and/or FMP receiver, and in step 1090, the DSP controller 1250 may turn on the most efficient FMP transmitter and/or FMP receiver. In addition, the DSP controller 1250 will update the identifiers for the FMP receivers/FMP transmitters at step 1072 because FMP transmitters and FMP receivers may be removed and/or inserted from time-to-time.

FIG. 12D illustrates a flow chart depicting a method 1270 according to an example embodiment. The method 1270 includes, at 1272, providing a first plurality of power receivers, each power receiver of the first plurality of power receivers being configured to receive power. At 1274, the method includes performing DC-to-DC isolation of an output of an associated power receiver of the first plurality of power receivers and to output isolated DC power from each power receiver of the first plurality of power receivers. At 1276, the method includes receiving, with a first bus bar configured to support communication of power, the isolated DC power for each of the power receivers of the first plurality of power receivers. At 1278, the method includes obtaining, with each of a first plurality of power transmitters connected to the first bus bar, power from one or more power receivers of the first plurality of power receivers. At 1280, the method includes obtaining, at a controller, via a first current share bus, measurements made by each power receiver of the first plurality of power receivers, the measurements indicating percentage of output current provided by each of the first plurality of power receivers, and at 1282, obtaining, at the controller, via a second current share bus, measurements made by each power transmitter of the first plurality of power transmitters, the measurements indicating percentage of output current provided by each of the power transmitters of the first plurality of power transmitters. At 1284, the method includes evaluating, by the controller, the measurements obtained from the power receivers of the first plurality of power receivers and the measurements obtained from the power transmitters of the first plurality of power transmitters. At 1286, the method includes, based on the evaluating, selecting, by the controller, one or more power receivers of the first plurality of power receivers to shut down or to power on in order to maintain operation of the first plurality of power receivers at a desired power efficiency, and selecting one of more power transmitters of the first plurality of power transmitters to shut down or to power on in order to maintain operation of the first plurality of power transmitters at a desired power efficiency.

### Out-of-Band Synchronization Between Power Transmitters and Power Receivers

Embodiments are provided below to enable synchronization between power switching (on/off) at power transmitters with the power switching (on/off) at power receivers through an out-of-band channel, that is, via a separate cable dedicated to carrying a synchronization (clock) signal.

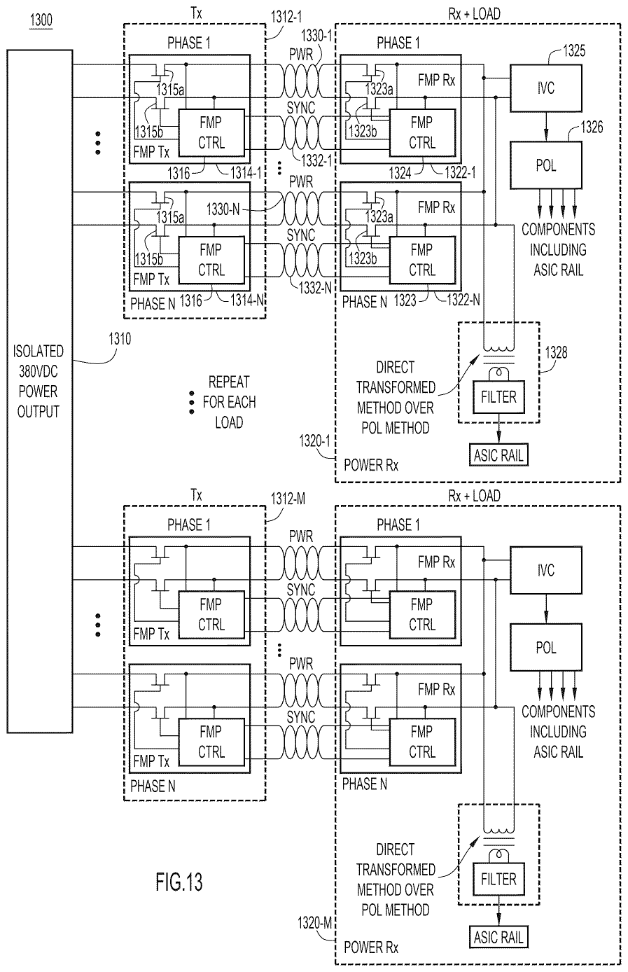

Reference is now made to FIG. 13, which illustrates a diagram of power distribution system 1300. FIG. 13 is similar to the diagram of FIG. 5A, but further includes an additional cable to carrying a synchronization signal (clock) between a power transmitter and a power receiver. More specifically, the power distribution system 1300 includes an isolated (380 Volts DC (VDC)) power source 1310, a plurality of power transmitter blocks 1312-1 to 1312-M, each comprising N FMP transmitters 1314-1 to 1314-N to output N phases of power. Each FMP transmitter 1314-1 to 1314-N includes a pair of FET switches 1315a and 1315b and an FMP controller (CTRL) 1316. The FMP CTRL 1316 controls the FET switches 1315a and 1315b for a given phase to connect/disconnect the DC power from being transmitted at its output when the FMP CTRL 1316 detects a fault and also during a safety check interval with the FMP CTRL 1316 causes the FET switches 1315a and 1315b to disconnect from the DC power in order to check the current and/or voltage on the lines with no power applied to the lines during the safety check interval. The details of the FMP CTRL 1316 are described above in connection with FIG. 5B.

The power distribution system 1300 further includes a plurality of power receiver blocks 1320-1 to 1320-M, each associated with a given load. Each power receiver block includes FMP receivers 1322-1 to 1322-N for the N phases of power from the N FMP transmitters of a power transmitter block. The FMP receivers 1322-1 to 1322-N are coupled by N power cables/wire pairs 1330-1 to 1330-N to the FMP transmitters 1314-1 to 1314-N. Further, there are a plurality of synchronization cables 1332-1 to 1332-N connected between FMP transmitters 1314-1 to 1314-N and FMP receivers 1322-1 to 1322-N.

Each FMP receiver 1322-1 to 1322-N includes a pair of FET switches 1323a and 1323b and an FMP CTRL 1324 connected to an associated pair of FET switches 1323a and 1323b. In addition, each power receiver block 1320-1 to 1320-M includes an integrated voltage controller (IVC) 1325 connected to a point-of-load (POL) 1326 that is configured to provide power supply voltage to one or more components, such as a rail voltage for an application integrated circuit (ASIC). Further still, each power receiver block 1320-1 to 1320-M may include transformer and filter circuitry 1328, similar to that shown in FIG. 2, to output an ASIC rail voltage.

The power cables 1330-1 to 1330-N carry power waveforms from the FMP transmitters 1314-1 to 1314-N to the FMP receivers 1322-1 to 1322-N. The synchronization cables 1332-1 to 1332-N carry synchronization signals (e.g., a clock waveform or signal) from the FMP transmitters 1314-1 to 1314-N to the FMP receivers 1322-1 to 1322-N. Thus, the synchronization signals are out-of-band with respect to the power waveform carried over the power cables 1330-1 to 1330-N since they are carried over entirely separate cables. As explained in more detail below, each FMP transmitter is configured to derive transmit power over an associated pair of lines in a power cable, and each FMP transmitter includes an FMP CTRL 1316 that is configured to perform a safety check to detect a fault with respect to the associated pair of lines. Similarly, each FMP receiver is configured to receive power from a pair of lines in a power cable from an associated power transmitter of the plurality of power transmitters, and each FMP receiver includes an FMP CTRL 1323 that configured to perform a safety check to detect a fault with respect to a pair of lines over which it receives power and to output power over a pair of output lines.

As explained above, the synchronization clock signal is sent from the power transmitters to the power receivers, through a low voltage path, to control the FET switches in the power receivers to disconnect at the appropriate timing to perform a safety check synchronized with the safety check that the power transmitters perform.

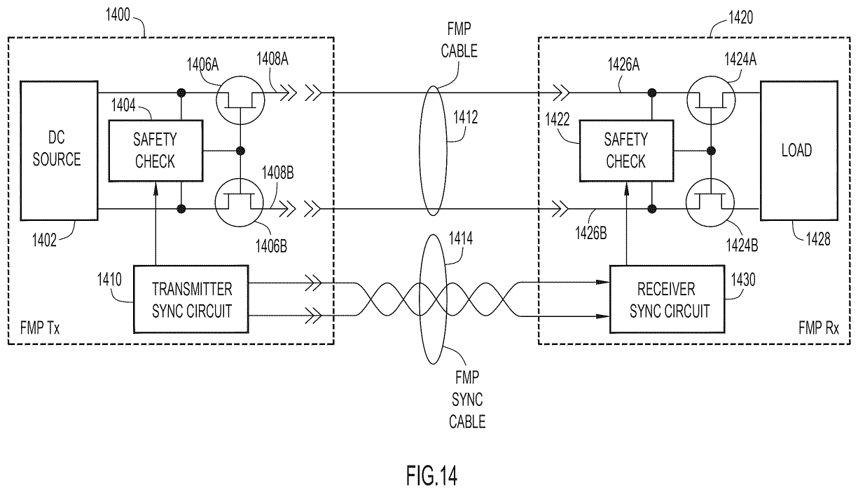

FIG. 14 shows a simplified block diagram of the relevant components of an FMP transmitter and an associated FMP receiver. The FMP transmitter 1400 includes a DC source 1402, a transmitter safety check (fault detector) block/circuit 1404, FET switches 1406A and 1406B that are connected to the transmitter safety check circuit 1404 and are controlled to connect/disconnect power from lines 1408A and 1408B, respectively. The transmitter safety check circuit 1404 is also connected to the lines 1408A and 1408B to monitor current and/or voltage on the lines for performing a fault detection. A transmitter sync circuit 1410 is provided in the FMP transmitter 1400 to provide a synchronization clock signal to the transmitter safety check circuit 1404 and also to output the synchronization clock signal. To this end, there is a power cable (also referred to as FMP cable) 1412 that carries the power waveform output by the FMP transmitter 1400, and a synchronization cable (also called FMP sync cable) 1414 that carries the synchronization clock signal output by the transmitter sync circuit 1410 of the FMP transmitter 1400. The synchronization clock signal may be a differential signal (having a positive (P) component and a negative (N) component).

The FMP receiver 1420 includes a receiver safety check block/circuit 1422, FET switches 1424A and 1424B to control the delivery of power received from the cable 1412 onto lines 1426A and 1426B, respectively, to a load 1428. The FMP receiver 1420 further includes a receiver sync circuit 1430 that receives the synchronization clock signal from the transmitter sync circuit 1410 over the synchronization cable 1414. The receiver sync circuit 1430 provides a synchronization signal to the safety check block 1422 to control when the safety check block 1422 opens and closes the FET switches 1424A and 1424B so that the opening of the FET switches 1424A and 1424B for short time durations when the safety check block 1422 performs a safety check/fault detection, is synchronized with the opening of the FET switches 1406A and 1406B at the FMP transmitter 1400 when the transmitter safety check circuit 1404 performs a safety check.

The synchronization cable 1414 may (or may not) be bundled with the power cable 1412.

Thus, as shown in FIG. 14, each FMP transmitter includes a transmitter synchronization circuit and each FMP receiver includes a receiver synchronization circuit in communication with the transmitter synchronization circuit of an FMP transmitter. The transmitter synchronization circuit is configured to generate a synchronization clock signal to be provided to the receiver synchronization circuit. The receiver synchronization circuit is configured to synchronize operation of fault detection operations of the FMP receiver with respect to fault detection operations performed by the FMP transmitter, which happens during power-off times of power that the FMP transmitter transmits over the associated power cable. These synchronization operations are described below in more detail.

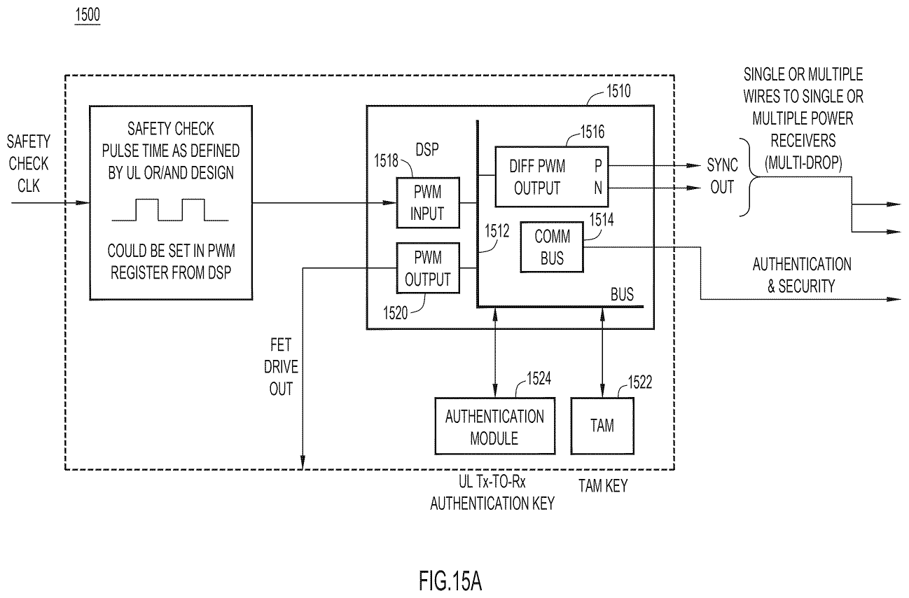

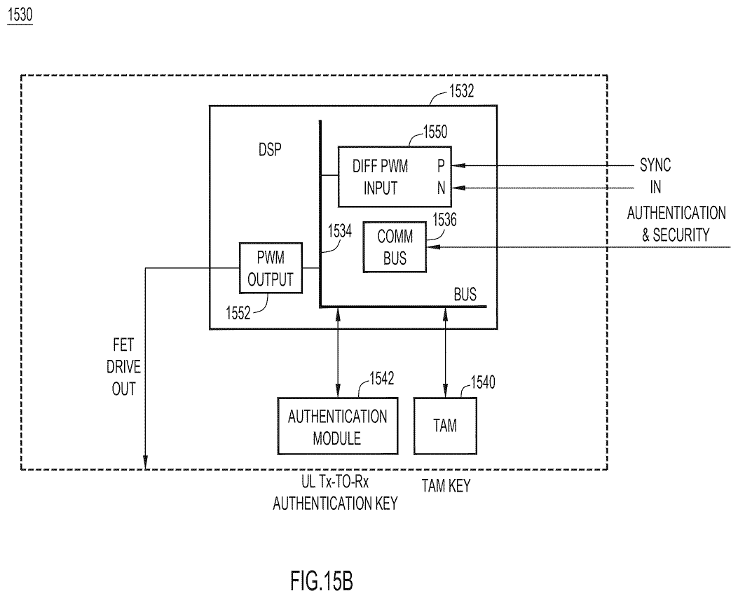

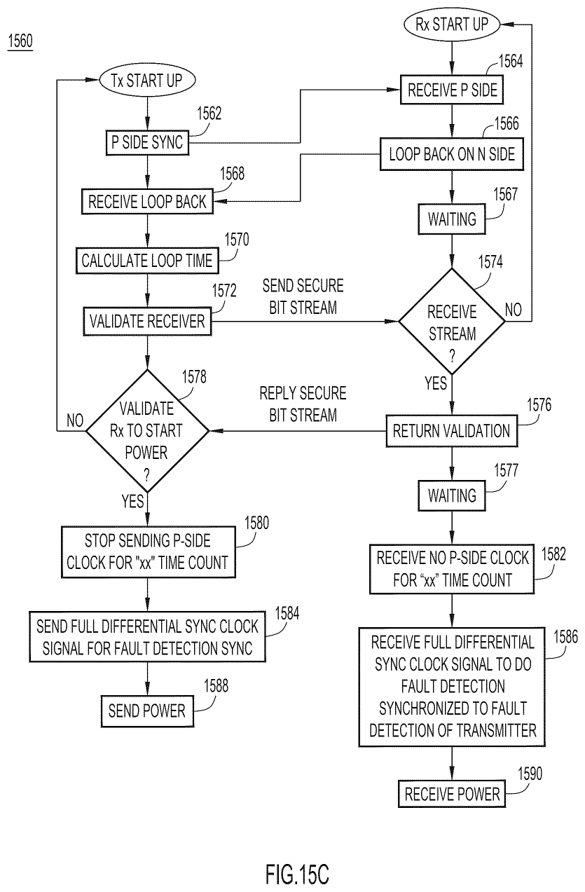

Reference is now made to FIGS. 15A and 15B. FIG. 15A is an example block diagram of the transmitter sync circuit shown in FIG. 14, and FIG. 15B is an example block diagram of the receiver sync circuit shown in FIG. 14.

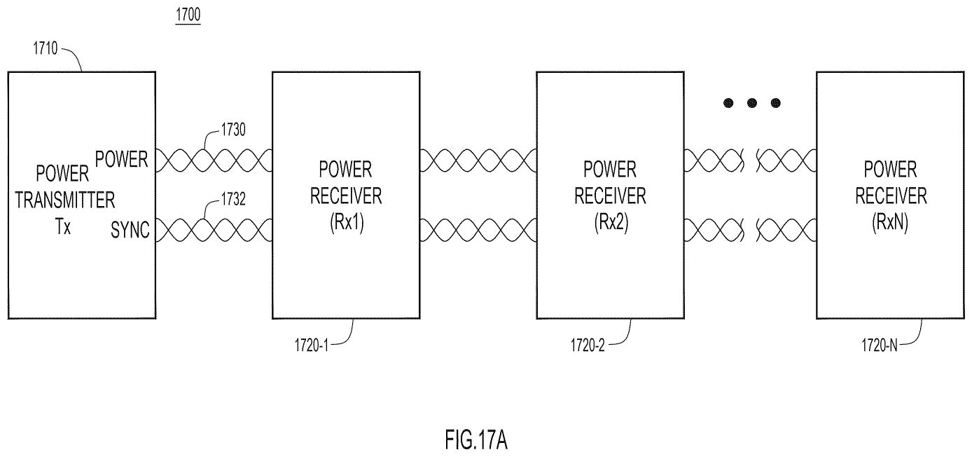

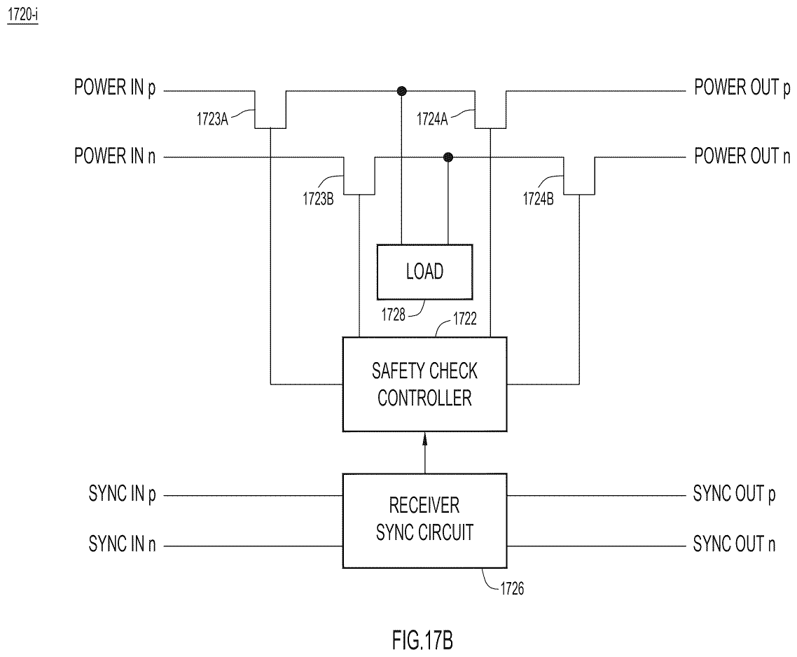

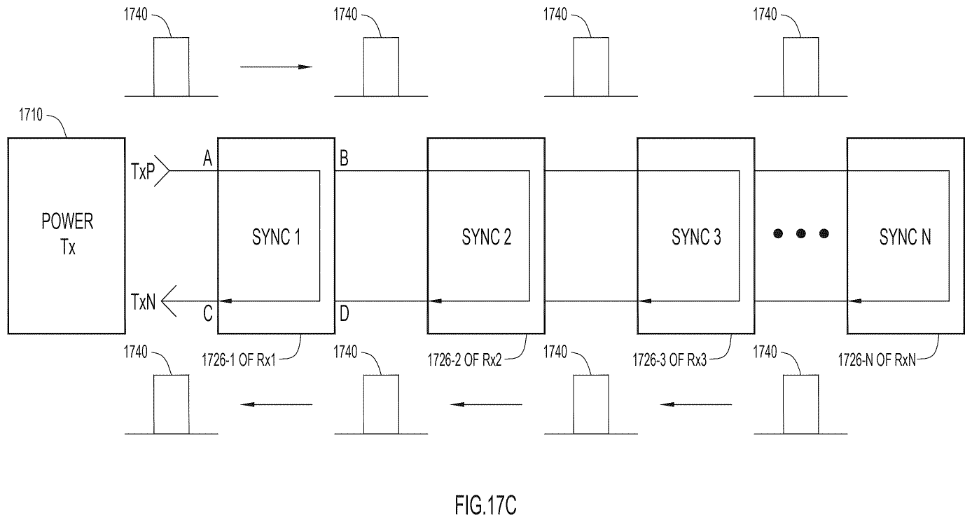

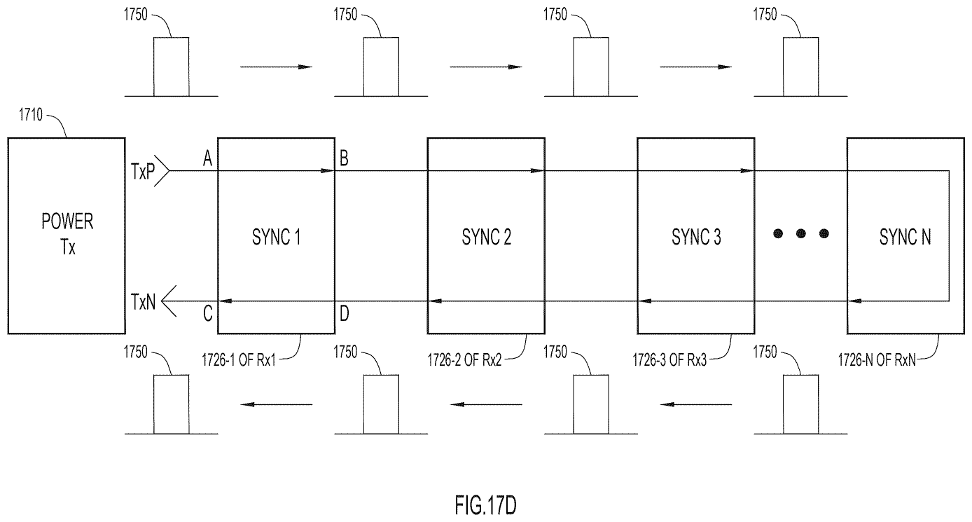

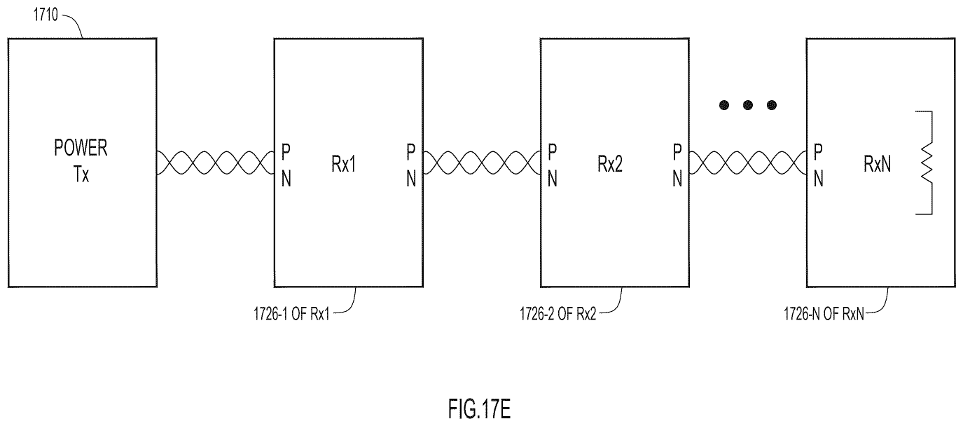

With reference first to FIG. 15A, a transmitter sync circuit 1500 may include a DSP or microprocessor 1510 that includes an internal bus 1512 and an external communication (com) bus 1514. The DSP 1510 may generate a differential pulse width modulated (PWM) synchronization output signal (with P and N components) 1516 to be provided to a receiver sync circuit. In one embodiment, the DSP 1510 generates the PWM synchronization output signal 1516 on its own, and in another embodiment, the DSP 1510 uses an externally provided (from another component in the FMP transmitter) safety check clock that is used to generate the PWM synchronization output signal 1516. There may be a safety check pulse time that defines the duration of the “off” time of the PWM synchronization output signal, which is defined by a safety standards body or certification authority, such as Underwriters Laboratory® (UL®), and/or can be set in a register, PWM input 1518 of the DSP 1510. The DSP 1510 also provides a PWM output 1520 to drive the safety check block, which in turn drives/controls the FET switches (shown at 1406A/1406B in FIG. 14) in the FMP transmitter. The DSP 1510 could be digital logic gates, an FPGA, processor or any suitable digital processing device. As shown in FIG. 15A, the transmitter sync circuit 1500 may output the synchronization clock signal (in single-end form or differential form having positive (P) and negative (N) signals) to a single power receiver, or two multiple power receivers in a multi-drop arrangement, the latter of which is described in more detail below in connection with FIG. 17A.

The transmitter sync circuit 1500 may further include a trust anchor module (TAM) 1522 and an authentication module 1524. These modules may be combined/integrated together or may be separate modules. The TAM 1522 stores a TAM key that is used for security purposes, and the authentication module 1524 stores a Tx-to-Rx authentication key that, for example, authenticates that the FMP transmitter in which the transmit sync circuit 1500 resides is approved by a regulatory or certification authority, such as UL, to operate with an FMP receiver. Communication between the TAM 1522 and the authentication module 1524 of the transmitter sync circuit and similar modules of the receiver sync circuit on the receive side may be via the com bus 1514.

Turning now to FIG. 15B, a receiver sync circuit 1530 is shown. The receiver sync circuit 1530 includes a DSP 1532, an internal bus 1534, a com bus 1536, a TAM 1540 and an authentication module 1542. The receive sync circuit 1530 receives (at Sync In) the PWM synchronization output signal (from the transmitter sync circuit 1500 of FIG. 15A) which serves as a differential PWM input 1550 to the DSP 1532 (after conversion to a digital signal). The DSP 1532 generates a PWM output 1552 that is provided by the receiver sync circuit 1530 to the safety check circuit (shown at 1422 in FIG. 14) of a host FMP receiver, to in turn control/drive the FET switches in the FMP receiver. In this way, the FMP receiver switches on/off the FET switches synchronized to the FET switches of the FMP transmitter that sent the PWM synchronization output signal. In addition, the receiver sync circuit 1530 establishes authentication and security verification with a transmitter sync circuit 1500 using the TAM 1540 and the authentication module 1542 which communicate with similar modules in the transmitter sync circuit 1500 via the com bus 1536, as described below.

The synchronization functionality is useful for the power pulse based fault detection techniques described above (based on current or voltage or a combination of voltage and current), where the power transmitter and power receiver need to disconnect from power for a fault detection time window, and then reconnect to the power after the fault detection time window is complete, assuming no fault is detected during that time window. Better and more precise synchronization between the power transmitter and power receiver allows for a shorter duration of the fault detection time window (to allow for fault detection at both ends), which means that more time can be spent with power connected at the power receiver, and thus obtaining power from the transmitted power waveform to deliver power to one or more power consuming devices.

The transmitter sync circuit 1500 and receiver sync circuit 1530 may verify the security/authenticity of each other using the TAM keys that each circuit stores. In addition, the transmitter sync circuit 1500 and receiver sync circuit 1530 may verify certification compliance (e.g., UL compliance) using the Tx-to-Rx authentication keys that each circuit stores. The com bus used for communication between the sync circuits could be Inter-Integrated Circuit (I2C), Cam bus, TIS single pair, RS-45, point-to-point, etc., and may be used as a separate out-of-band channel, from the channel used for synchronization, specifically dedicated to authentication using the authentication modules and security verification using the TAMs. Thus, there may be essentially three channels between the power transmitter and the power receiver(s): a first channel to carry power from the power transmitter to the power receiver(s) (e.g., a dedicated power cable), a second channel to carrying the synchronization clock signal (pulses) (e.g., a dedicated sync cable), and a third channel to enable communications between the power transmitter and the power receiver(s) to do authentication and security verification.

The digital fuse fault detection techniques described above do not need synchronization between the power transmitter and power receiver to detect a fault. However, the sync circuits can be useful for the Tx-to-Rx authentication and security authentication/verification. The sync circuit can also be useful for driving the on/off pulses when a transformer is deployed at the load on the power receiver side.

FIG. 15C illustrates a flow diagram 1560 depicting the cooperative operation of the transmit sync circuit 1500 and the receiver sync circuit 1530 for synchronization, authentication and security verification. During an initialization or startup phase, at 1562, the transmitter sync circuit 1500 of a power transmitter sends a synchronization clock signal only from the P side of to the P side of the power receiver that is received at 1564. At 1566, the power receiver loops the synchronization signal back on the N side to the power transmitter and the power transmitter receives the loop back of the synchronization on the N side at 1568. At 1567, the power receiver is in a waiting state for a next communication from the power transmitter. This allows the power transmitter, at 1570, to calculate the loop time or propagation delay between the power transmitter and power receiver. The power transmitter may use the propagation delay to add a pre-delay to the synchronization clock signal to ensure that the power transmitter and the power receiver disconnect their FET switches at the same time during a safety check time window.

Next, the power transmitter does a security validation and authentication of the power receiver, via the separate com bus channel referred to above in connection with FIGS. 15A and 15B. At 1572, the power transmitter may send to the power receiver a secure bitstream that includes the authentication key and the TAM key of the power transmitter. At 1574, the power receiver determines whether it receives a secure bitstream, and if so, it evaluates the authentication key from the power transmitter to confirm it is a certified device, and evaluates the TAM key to verify the security of the power transmitter (it is valid power transmitter that the power receiver should trust and thus operate with). If the power receiver validates the authentication key and the TAM key from the power transmitter, then at 1576, the power receiver returns its authentication key and TAM key to the power transmitter, and enters a waiting state at 1577. At 1578, the power transmitter uses the authentication of the power receiver to confirm that it is a certified device, and likewise evaluates the TAM key of the power receiver to verify the security of the power receiver (it is a valid power receiver that the power transmitter should trust and operate with).

After the authentication and security validations are completed, the power transmitter can move to powering the power receiver. At 1580, the power transmitter may stop sending the synchronization clock signal on the P side wire for a period of time (“xx” time count). At 1582, when the power receiver sees no clock pulses on the P side for the period of time (“xx” time count), the power receiver knows to next look for the full differential synchronization clock signal. Thus, at 1584, the power transmitter sends the full differential synchronization clock signal to the power receiver. At 1586, the power receiver receives the full differential synchronization clock signal and then the power receiver can then synchronize to the power transmitter so that both the power receiver and power transmitter do fault detection at the same time (by shutting off the FET switches (opening them) at the same time). Thus, at 1588, the power transmitter sends power to the receiver and at 1590, the power receiver receives power.

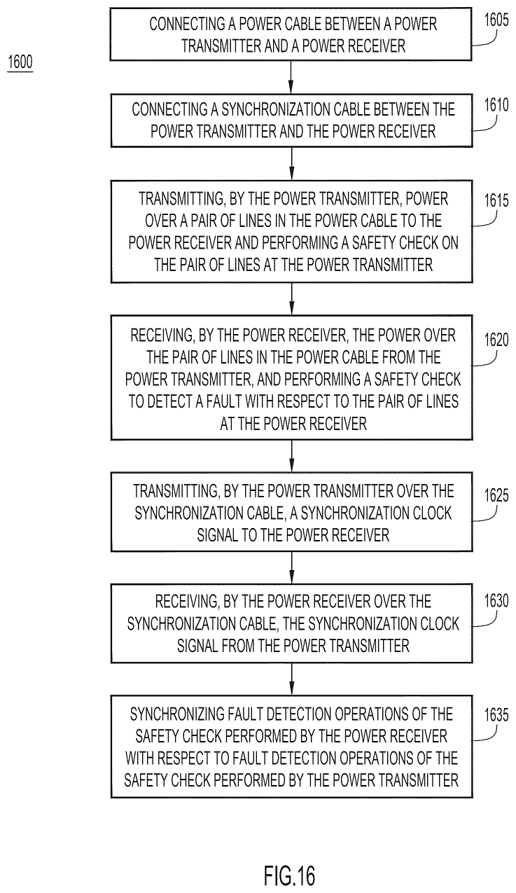

Reference is now made to FIG. 16. FIG. 16 shows a flow chart depicting a method 1600 for synchronizing the safety operations performed by a power transmitter and a power receiver, according to an example embodiment. There is no required order to these operations. The method 1600 includes, at 1605, connecting a power cable between a power transmitter and a power receiver, and at 1610, connecting a synchronization cable between the power transmitter and the power receiver. At 1615, the method includes transmitting, by the power transmitter, power over a pair of lines in the power cable to the power receiver and performing a safety check on the pair of lines at the power transmitter. At 1620, the method includes receiving, by the power receiver, the power over the pair of lines in the power cable from the power transmitter, and performing a safety check to detect a fault with respect to the pair of lines at the power receiver. At 1625, the method includes transmitting, by the power transmitter over the synchronization cable, a synchronization clock signal to the power receiver, and at 1630, the method includes receiving, by the power receiver over the synchronization cable, the synchronization clock signal from the power transmitter. At 1635, the method includes synchronizing fault detection operations of the safety check performed by the power receiver with respect to fault detection operations of the safety check performed by the power transmitter.

As explained above, the synchronizing operations at 1635 may involve determining, based on the synchronization clock signal, when to cause switches, connected to the pair of lines at the power transmitter, to disconnect from the pair of lines for a safety check time interval during which the fault detection operations are performed by the power transmitter; and determining, based on the synchronization clock signal, when to cause switches, connected to the pair of lines at the power receiver, to disconnect from the pair of lines for a safety check time interval during which the fault detection operations are performed by the power receiver.

Moreover, as explained above, the synchronization clock signal may be a differential signal. In this case, the method 1600 may further include: at the power transmitter, generating a differential pulse width modulated (PWM) synchronization clock signal to be output over the synchronization cable and to be used to by the power transmitter to determine when to cause switches, connected to the pair of lines at the power transmitter, to disconnect from the pair of lines; and at the power receiver, receiving the differential PWM synchronization clock signal over the synchronization cable and to use the differential PWM synchronization clock signal control when to cause switches, connected to the pair of lines at the power receiver, to disconnect from the pair of lines.

Further still, the method 1600 may include: at the power transmitter, sending the differential PWM synchronization clock signal over a first output of a pair of differential outputs to a first input of a pair of differential inputs of the power receiver; at the power receiver, receiving the differential to loop back the differential PWM synchronization clock signal via a second input of the pair of differential inputs to a second output of the pair of differential outputs of the power transmitter; and at the power transmitter, deriving a measure of propagation delay between the power transmitter and the power receiver in order to provide a pre-delay to the differential PWM synchronization clock signal to account for the propagation delay.

Moreover, the method 1600 may further include: at the power transmitter, sending to the power receiver an authentication key and a security key; at the power receiver, receiving the authentication key and the security key sent from the power transmitter and evaluating the authentication key and the security key of the power transmitter to validate that the power transmitter is a certified power transmitter and can be trusted; and sending from the power receiver to the power transmitter an authentication key and a security key of the power receiver to enable the power transmitter to validate that the power receiver is a certified power receiver and can be trusted.

### Multi-Drop Out-of-Band Synchronization

This out-of-band synchronization concepts described above in connection with FIGS. 15A-15C may be applied to a multi-drop arrangement. Reference is now made to FIGS. 17A and 17B. FIG. 17A shows a multi-drop power distribution system 1700 that includes a power transmitter 1710 and a plurality of power receivers 1720-1 to 1720-N, denoted Rx₁ to Rx_{N}, connected in a daisy-chain or multi-drop fashion. The power transmitter 1710 outputs a power waveform (Power) and a synchronization signal/waveform (Sync) to the first power receiver 1720-1 in the chain via a power cable 1730 and a sync cable 1732. Power receiver 1720-1 receives the power waveform and synchronization waveform from the power transmitter 1710, uses them, and passes them on to power receiver 1720-2, which does the same and so on, until power receiver 1720-N is reached.

FIG. 17B shows a block diagram of a power receiver 1720-i representative of any of the power receivers 1720-1 to 1720-N in FIG. 17A. A power receiver includes a safety check controller 1722, FET switches 1723A and 1723B at differential (P and N) power inputs, FET switches 1724A and 1724B at differential (P and N) power outputs, a receiver sync circuit 1726 and a load 1728. The receiver sync circuits 1726 receives a differential synchronization signal (P and N) at differential sync inputs (SyncIn_{P} and SyncIn_{N}) and passes the differential synchronization signal to differential sync outputs (SyncOut_{P} and SyncOut_{N}). The transmitter and receiver sync circuits may contain a trust anchor module and authentication module as previously described in connection with FIGS. 15A-15C.

The safety check controller 1722 controls the opening/closing of the FET switches 1723A and 1723B and 1724A and 1724B based on a timing signal provided by the receiver sync circuit 1726 and derived from the synchronization signal received by the receiver sync circuit 1726. In one example, the receiver sync circuit 1726 takes the form of the receive sync block shown in FIG. 15B and operates according to the techniques depicted in FIG. 15C. In addition, the receiver sync circuit 1726 passes on the differential synchronization signal at different synchronization outputs, to be coupled to the next power receiver.

Reference is now made to FIG. 17C. During an initialization stage, the devices operate in a single-ended mode, rather than a differential mode, with respect to handling of synchronization clock signals/pulses. The receiver sync circuit 1726-1 connects the sync output P, labeled “B” to the sync output N, labeled “D”. Receiver sync circuits 1726-2, 1726-3, . . . , 1726-N, all make the same connection between sync output B and sync output D. The power transmitter 1710 provides a first synchronization pulse 1740 to sync input A of receiver sync circuit 1726-1. The receiver sync circuit 1726-1 also sends out the first synchronization pulse 1740 at the sync output labeled B to the next power receiver. Each of the receiver sync circuits will monitor their sync output D to see if there is a return of a sync pulse, which indicates that there is a follow on downstream or follow-on power receiver. When a receiver sync circuit sees a synchronization pulse on sync output D, it removes the B-D connection/loop. Thus, as shown in FIG. 17D, the receiver sync circuits 1726-1, 1726-2 and 1726-3 all will remove the B-D connection/loop, but receiver sync circuit 1726-N will not remove that loop because it will not have detected the first synchronization pulse 1740 on the sync output D, since there is not another receiver sync circuit of a downstream power receiver to send it.

The power transmitter 1710 then sends a second synchronization pulse 1750 to the power receiver associated with receiver sync circuit 1726-1, which forwards it on to receiver sync circuit 1726-2 of the next power receiver, and so on, until it reaches the receiver sync circuit 1726-N, which loops it back from sync output B to sync output D, and then it returns through the receiver sync circuits 1726-3, 1726-2, 1726-1, and eventually back to the power transmitter. This allows the DSP of the receiver sync circuits to measure delays associated with propagation of the second synchronization pulse down the chain. The DSP of each of the receiver sync circuits sends the delay measurements back to the power transmitter, and to the receiver sync circuits of the other power receivers. A suitable signaling protocol may be used to allow the receiver sync circuits of the power receivers to send the delay measurement data that each makes to the other power receivers via the sync input pins and output pins of each sync block, and with the power transmitter. Thus, at some point, the power transmitter and the power receivers all know the delays associated with a sync pulse propagating down the multi-drop chain of power receivers. The transmitter sync block of the power transmitter 1710 can then add a pre-delay to the synchronization waveform and the power receivers wait out their respective delays before shutting off power to enable a safety check, but as a result, all devices turn off simultaneously to perform a safety check. This singled-end synchronization arrangement may involve use of a loop return on earth ground or a “third” pin to serve as a ground reference on each device.

During normal operation, after the initialization stage, the system can operate in a singled-ended arrangement and use the loop, depicted in FIG. 17D, as an additional safety check, or the system can switch to a differential mode where the synchronization signal is a differential signal that is passed on from one power receiver to another power receiver in the multi-drop chain, and power is terminated at R×N, the last power receiver in the chain. The latter arrangement is shown in FIG. 17E.

In a backplane or a rack deployment of power receivers, the propagation delay may be so small that it may not be necessary to compute a propagation delay using the sync signal arrangement for multi-drop described above. As such, the sync signal can be sent via dedicated wire to the first receiver in the chain, and then passed on via a dedicated wire to the next receiver in the chain and so on. No loopback would be needed. Thus, one example arrangement may be as shown in FIG. 15A, described above.

Thus, as depicted in FIGS. 17A-17E, a system is provided comprising: a power transmitter configured to output a power waveform, the power transmitter including a transmitter synchronization circuit and a transmitter safety check circuit, the transmitter synchronization circuit configured to generate a synchronization clock signal that synchronizes operation of the transmitter safety check circuit; a plurality of power receivers connected in a multi-drop arrangement, a first power receiver of the plurality of power receivers being connected to the power transmitter; a power cable including a pair of conductors to carry power from the power transmitter to the first power receiver; and a synchronization cable including a pair of conductors to carry the synchronization clock signal from the power transmitter to the first power receiver; wherein each power receiver of the plurality of power receivers includes: differential power inputs to receive the power waveform; differential power outputs to output the power waveform to a downstream power receiver of the plurality of power receivers; a receiver safety check circuit; differential synchronization inputs to receive the synchronization clock signal for use by the receiver safety check circuit; differential synchronization outputs to output the synchronization clock signal to a downstream power receiver; and a receiver synchronization circuit that control of the receiver safety check circuit based on the synchronization clock signal.

Further, during an initialization stage, each of the plurality of power receivers connects its differential synchronization outputs to each other, while the power transmitter transmits a first synchronization pulse to a first input of the differential synchronization inputs of the first power receiver, each power receiver of the plurality of power receivers transmitting the first synchronization pulse to first input of the differential synchronization inputs of a downstream power receiver, and each power receiver of the plurality of power receivers monitoring a second input of the differential synchronization outputs to determine whether there is a return of the first synchronization pulse from a downstream power receiver, and in response there, disconnecting the connection of its differential synchronization outputs to each other, thereby indicating to each power receiver whether there is a downstream power receiver.

Moreover, the power transmitter sends a second synchronization pulse to the first power receiver, which forwards it to a next power receiver of the plurality of power receivers, until reaching a last power receiver in the multi-drop arrangement, which loops the second synchronization pulse back to the power transmitter via the power receivers in the multi-drop arrangement, wherein the power transmitter is configured to measure delays associated with propagation of the second synchronization pulse through the plurality of power receivers based on measurements obtained from each of the plurality of power receivers and is configured add a pre-delay to the synchronization clock signal to cause each of the plurality of power receivers to wait out a respective delay before initiating a safety check operation.

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi-Fi®/Wi-Fi6®), IEEE 802.16 (e.g., Worldwide Interoperability for Microwave Access (WiMAX)), Radio-Frequency Identification (RFID), Near Field Communication (NFC), Bluetooth™, mm.wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

To the extent that embodiments presented herein relate to the storage of data, the embodiments may employ any number of any conventional or other databases, data stores or storage structures (e.g., files, databases, data structures, data or other repositories, etc.) to store information.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

In some aspects, the techniques described herein relate to a system including: a power source configured to output electrical power; one or more isolation transformers coupled to the power source and configured to output Direct Current (DC) power; a plurality of power transmitters coupled to receive the DC power and each power transmitter configured to transmit power, derived from the DC power, over an associated pair of lines, each power transmitter configured to perform a safety check to detect a fault with respect to the associated pair of lines; and a plurality of power receivers each configured to receive power from a pair of lines from an associated power transmitter of the plurality of power transmitters, each power receiver configured to perform a safety check to detect a fault with respect to a pair of lines over which it receives power and to output power over a pair of output lines, wherein respective output lines of the pair of output lines of the plurality of power receivers being coupled to each other.

In some aspects, the techniques described herein relate to a system, further including a plurality of DC-to-DC isolation circuits each coupled to receive output power from a corresponding power receiver of the plurality of power receivers and configured to output isolated DC power on the pair of output lines of the corresponding power receiver.

In some aspects, the techniques described herein relate to a system, further including, coupled to the respective output lines of the plurality of power receivers: a step-down transformer configured to step down a voltage of power output by a power receiver or a step-up transformer configured to step up a voltage of power output by a power receiver.

In some aspects, the techniques described herein relate to a system, further including, coupled to the respective output lines of the plurality of power receivers, an integrated voltage controller and a point-of-load.

In some aspects, the techniques described herein relate to a system, wherein the pair of lines are carried in associated cables extending between a respective power transmitter of the plurality of power transmitters and a respective power receiver of the plurality of power receivers.

In some aspects, the techniques described herein relate to a system, wherein each power transmitter includes a fault detector configured to detect a fault on the associated pair of lines, and each power receiver includes a fault detector configured to detect a fault on the associated pair of lines.

In some aspects, the techniques described herein relate to a system, wherein the fault detector at each power transmitter and the fault detector at each power are configured to monitor an impedance level to determine characteristics of a human touch fault.

In some aspects, the techniques described herein relate to a system, wherein each power transmitter is configured to transmit pulse power over the associated pair of lines to a corresponding power receiver, and wherein the pulse power includes periods of power-off times and periods of power-on times between successive power-off times, and wherein the fault detector at each power transmitter and the fault detector at the corresponding power receiver are synchronized to detect a fault during power-off times of the pulse power.

In some aspects, the techniques described herein relate to a system, wherein each pair of lines coupled between each respective power transmitter and corresponding power receiver is included in a power cable connected between the respective power transmitter and the corresponding power receiver, and further including a synchronization cable connected between each respective power transmitter and the corresponding power receiver, wherein each respective power transmitter further includes a transmit synchronization circuit and each corresponding power receiver further includes a receiver synchronization circuit in communication with the transmit synchronization circuit of the respective power transmitter, wherein the transmit synchronization circuit is configured to generate a synchronization clock signal sent to the receiver synchronization circuit via the synchronization cable between each respective power transmitter and the corresponding power receiver.

In some aspects, the techniques described herein relate to a system, wherein the receiver synchronization circuit in each corresponding power receiver is configured to synchronize operation of fault detection operations of the power receiver with respect to power-off times of power provided by the respective power transmitter over the power cable.

In some aspects, the techniques described herein relate to a system including: a power source configured to output isolated Direct Current (DC) power; a plurality of power transmitters coupled to receive the DC power and each power transmitter configured to transmit power, derived from the DC power, over an associated pair of lines, each power transmitter configured to perform a safety check to detect a fault with respect to the associated pair of lines; a plurality of power receivers each configured to receive power from a pair of lines from an associated power transmitter of the plurality of power transmitters, each power receiver configured to perform a safety check to detect a fault with respect to a pair of lines over which it receives power and to output power over a pair of output lines, wherein respective output lines of the pair of output lines of the plurality of power receivers being coupled to each other; and a plurality of DC-to-DC isolation circuits each coupled to receive output power from a corresponding power receiver of the plurality of power receivers and configured to output isolated DC power on the pair of output lines of the corresponding power receiver.

In some aspects, the techniques described herein relate to a system, further including one or more isolation transformers coupled to the power source and configured to output the DC power.

In some aspects, the techniques described herein relate to a system, further including, coupled to the respective output lines of the plurality of power receivers: a step-down transformer configured to step down a voltage of power output by a power receiver or a step-up transformer configured to step up a voltage of power output by a power receiver.

In some aspects, the techniques described herein relate to a system, further including, coupled to the respective output lines of the plurality of power receivers, an integrated voltage controller and a point-of-load.

In some aspects, the techniques described herein relate to a system, wherein each power transmitter includes a fault detector configured to detect a fault on the associated pair of lines, and each power receiver includes a fault detector configured to detect a fault on the associated pair of lines.

In some aspects, the techniques described herein relate to a system, wherein the fault detector at each power transmitter and the fault detector at each power are configured to monitor an impedance level to determine characteristics of a human touch fault.

In some aspects, the techniques described herein relate to a system, wherein each power transmitter is configured to transmit pulse power over the associated pair of lines to a corresponding power receiver, and wherein the pulse power includes periods of power-off times and periods of power-on times between successive power-off times, and wherein the fault detector at each power transmitter and the fault detector at the corresponding power receiver are synchronized to detect a fault during power-off times of the pulse power.

In some aspects, the techniques described herein relate to a system, wherein each pair of lines coupled between each respective power transmitter and corresponding power receiver is included in a power cable connected between the respective power transmitter and the corresponding power receiver, and further including a synchronization cable connected between each respective power transmitter and the corresponding power receiver, wherein each respective power transmitter further includes a transmit synchronization circuit and each corresponding power receiver further includes a receive synchronization circuit in communication with the transmit synchronization circuit of the respective power transmitter, wherein the transmit synchronization circuit is configured to generate a synchronization clock signal sent to the receiver synchronization circuit via the synchronization cable between each respective power transmitter and the corresponding power receiver.

In some aspects, the techniques described herein relate to a method including: providing one or more isolation transformers coupled to an electrical power source to output Direct Current (DC) power derived from the electrical power source; transmitting, by each of a plurality of power transmitters coupled to receive the DC power, power, derived from the DC power, over an associated pair of lines; performing a safety check at each power transmitter to detect a fault with respect to the associated pair of lines; receiving at a plurality of power receivers, power from a pair of lines from an associated power transmitter of the plurality of power transmitters; performing a safety check at each power receiver to detect a fault with respect to a pair of lines over which each power receiver receives power to output power over a pair of output lines; and connecting output lines of the pair of output lines of the plurality of power receivers to each other.

In some aspects, the techniques described herein relate to a method, wherein transmitting includes transmitting pulse power over the associated pair of lines to a corresponding power receiver, and wherein the pulse power includes periods of power-off times and periods of power-on times between successive power-off times, and wherein performing fault detection at each power transmitter and performing fault detection at the corresponding power receiver is synchronized to detect a fault during power-off times of the pulse power.

In some aspects, the techniques described herein relate to a method, further including: connecting each pair of lines between each respective power transmitter and corresponding power receiver in a power cable connected between the respective power transmitter and the corresponding power receiver; connecting a synchronization cable between each respective power transmitter and the corresponding power receiver, and transmitting from each respective power transmitter a synchronization clock signal to the corresponding power receiver to synchronize the performing of fault detection at the corresponding power receiver with the performing of fault detection at the respective power transmitter.

In some aspects, the techniques described herein relate to a system including: a bus bar that that is configured to support communication of power; a plurality of power receivers coupled to the bus bar, each power receiver configured receive a supplied power and to provide an output power to the bus bar, each power receiver further configured to detect a fault in the output power provided to the bus bar; and one or more power consuming devices connected to the bus bar and configured to receive and consume power provided by a power receiver of the plurality of power receivers.

In some aspects, the techniques described herein relate to a system, further including: at least one fault detector coupled to the bus bar and configured to monitor an impedance level on the bus bar to detect a fault.

In some aspects, the techniques described herein relate to a system, further including: a Direct Current (DC) power supply configured to provide DC power; and a switch circuit connected to the DC power supply and to the bus bar, wherein the switch circuit is configured to either connect the DC power supply to the bus bar to provide the supplied power to the bus power or to disconnect the DC power supply from the bus bar, wherein the at least one fault detector is configured to output a switch control signal to cause the switch circuit to disconnect the DC power supply from the bus bar upon detecting a fault on the bus bar.

In some aspects, the techniques described herein relate to a system, further including two or more fault detectors connected to different locations of the bus bar to detect a fault on the bus bar.

In some aspects, the techniques described herein relate to a system, further including a plurality of power consuming devices connected to the bus bar and to receive power from the bus bar.

In some aspects, the techniques described herein relate to a system, further including a plurality of power transmitters connected to the bus bar and configured to provide power to the plurality of power receivers via the bus bar.

In some aspects, the techniques described herein relate to a system, wherein each of the plurality of power transmitters are configured to detect a fault on power provided to the bus bar.

In some aspects, the techniques described herein relate to a system, further including a controller in communication with the plurality of power transmitters via a current share bus to receive measurements made by each of the plurality of power transmitters, the measurements indicating percentage of output current provided by each of the plurality of power transmitters, and wherein the controller is configured to evaluate the measurements to select one or more of the plurality of power transmitters to shut down in order to maintain operation of the plurality of power transmitters at a desired power efficiency.

In some aspects, the techniques described herein relate to a system, wherein the plurality of power receivers are each configured to provide measurements indicating a percentage of output current of power provided to the bus bar, and wherein the plurality of power receivers are arranged in a corresponding set of a plurality of sets, each set including multiple power receivers each dedicated to provide power in one phase of a plurality of phases, and wherein the controller is configured to control power receivers within each set to selectively shut down one or more power receivers in a set based on the measurements received from the power receivers in order to achieve a desired power efficiency within a set, and/or to control power receivers across sets to selectively shut down one or more power receives based on the measurements received from the power receivers in order to achieve a desired power efficiency across the sets.

In some aspects, the techniques described herein relate to a system, wherein the plurality of power receivers are configured to mount into one or more power shelves of a rack and the plurality of power consuming devices are configured to mount into one or more shelves of the rack.

In some aspects, the techniques described herein relate to a system including: a first plurality of power receivers, each power receiver of the first plurality of power receivers being configured receive power; a plurality of DC-to-DC isolation circuits, each coupled to an output of an associated power receiver of the first plurality of power receivers and configured to output isolated DC power; a first bus bar configured to support communication of power, wherein the first bus bar receives the isolated DC power from each of the plurality of DC-to-DC isolation circuits; a first plurality of power transmitters each of which is connected to the first bus bar to receive power from one or more power receivers of the first plurality of power receivers; and a controller in communication with the first plurality of power receivers via a first current share bus to receive measurements made by each power receiver of the first plurality of power receivers, the measurements indicating percentage of output current provided by each power receiver of the first plurality of power receivers, and the controller is in communication with each power transmitter of the first plurality of power transmitters via a second current share bus to receive measurements made by each power transmitter of the first plurality of power transmitters, the measurements indicating percentage of output current provided by each power transmitter of the first plurality of power transmitters, wherein the controller is configured to evaluate the measurements from power receiver of the first plurality of power receivers and the measurements from power transmitters of the first plurality of power transmitters to select one or more power receivers of the first plurality of power receivers to shut down or to power on in order to maintain operation of the first plurality of power receivers at a desired power efficiency, and to select one of more power transmitters of the first plurality of power transmitters to shut down or to power on in order to maintain operation of the first plurality of power transmitters at a desired power efficiency.

In some aspects, the techniques described herein relate to a system, wherein the controller is configured to shut down a power transmitter of the first plurality of power transmitters that the controller determines to be most inefficient among the first plurality of power transmitters and/or to shut down a power receiver of the first plurality of power receivers that the controller determines to be most inefficient among the first plurality of power receivers, and the controller is configured to turn on a power transmitter of the first plurality of power transmitters that the controller determines to be most efficient among the first plurality of power transmitters and/or to turn on a power receiver of the first plurality of power receivers that the controller determines to be most efficient among the first plurality of power receivers.

In some aspects, the techniques described herein relate to a system, wherein the power receivers of the first plurality of power receivers are arranged in a corresponding set of a plurality of sets, each set including multiple power receivers each dedicated to provide power in one phase of a plurality of phases, and wherein the controller is configured to control power receivers within each set to selectively shut down one or more power receivers in a set based on the measurements received from the power receivers in order to achieve a desired power efficiency within a set, and/or to control power receivers across sets to selectively shut down one or more power receivers based on the measurements received from the power receivers in order to achieve a desired power efficiency across the sets.

In some aspects, the techniques described herein relate to a system, further including: a second bus bar configured to support communication of power, the second bus bar configured to receive power output by the first plurality of power transmitters; and a second plurality of power receivers connected to the second bus bar to receive power from one or more of the first plurality of power transmitters.

In some aspects, the techniques described herein relate to a system, further including a plurality of power consuming devices each including a power receiver of the second plurality of power receivers, each power consuming device including a point of load configured to consume power obtained by the power receiver of the power consuming device.

In some aspects, the techniques described herein relate to a system, further including: a plurality of power consuming devices, each power consuming device including a power receiver configured to receive power and a point of load configured to consume power obtained by the power receiver of the power consuming device, wherein the first plurality of power transmitters includes a plurality of redundant pairs of power transmitters, each redundant pair dedicated for providing power to a corresponding power consuming device of the plurality of power consuming devices.

In some aspects, the techniques described herein relate to a system, further including a pair of cables each carrying a wire pair, wherein each pair of cables connects between each redundant pair of power transmitters to the corresponding power consuming device of the plurality of power consuming devices.

In some aspects, the techniques described herein relate to a system, further including: a second bus bar that that is configured to support communication of power; and one or more power sources configured to output source power to the second bus bar; a second plurality of power transmitters, each of which is configured to obtain power from the second bus bar and to transmit power, over an associated cable, to a respective power receiver of the first plurality of power receivers.

In some aspects, the techniques described herein relate to a method including: providing a first plurality of power receivers, each power receiver of the first plurality of power receivers being configured receive power; performing DC-to-DC isolation of an output of an associated power receiver of the first plurality of power receivers and to output isolated DC power from each power receiver of the first plurality of power receivers; receiving, with a first bus bar configured to support communication of power, the isolated DC power for each of the power receivers of the first plurality of power receivers; obtaining, with each of a first plurality of power transmitters connected to the first bus bar, power from one or more power receivers of the first plurality of power receivers; obtaining, at a controller, via a first current share bus, measurements made by each power receiver of the first plurality of power receivers, the measurements indicating percentage of output current provided by each of the first plurality of power receivers; obtaining, at the controller, via a second current share bus, measurements made by each power transmitter of the first plurality of power transmitters, the measurements indicating percentage of output current provided by each of the power transmitters of the first plurality of power transmitters, evaluating, by the controller, the measurements obtained from the power receivers of the first plurality of power receivers and the measurements obtained from the power transmitters of the first plurality of power transmitters; and based on the evaluating, selecting, by the controller, one or more power receivers of the first plurality of power receivers to shut down or to power on in order to maintain operation of the first plurality of power receivers at a desired power efficiency, and selecting one of more power transmitters of the first plurality of power transmitters to shut down or to power on in order to maintain operation of the first plurality of power transmitters at a desired power efficiency.

In some aspects, the techniques described herein relate to a method, further including: by the controller, shutting down a power transmitter of the first plurality of power transmitters that the controller determines to be most inefficient among the first plurality of power transmitters and/or shutting down a power receiver of the first plurality of power receivers that the controller determines to be most inefficient among the first plurality of power receivers; and by the controller, turning on a power transmitter of the first plurality of power transmitters that the controller determines to be most efficient among the first plurality of power transmitters and/or turning on a power receiver of the first plurality of power receivers that the controller determines to be most efficient among the first plurality of power receivers.

In some aspects, the techniques described herein relate to a method, wherein the power receivers of the first plurality of power receivers are arranged in a corresponding set of a plurality of sets, each set including multiple power receivers each dedicated to provide power in one phase of a plurality of phases, further including: the controller selectively shutting down one or more power receivers in a set based on the measurements received from the power receivers in order to achieve a desired power efficiency within a set, and/or selectively shutting down one or more power receivers based on the measurements received from the power receivers in order to achieve a desired power efficiency across the sets.

In some aspects, the techniques described herein relate to a method, further including: receiving at a second bus bar power output by the first plurality of power transmitters; and connecting a second plurality of power receivers to the second bus bar to receive power from one or more of the first plurality of power transmitters.

In some aspects, the techniques described herein relate to a system including: a power transmitter; a power receiver; a power cable connected between the power transmitter and the power receiver; a synchronization cable connected between the power transmitter and the power receiver; the power transmitter being coupled to receive Direct Current (DC) power and to transmit power, derived from the DC power, over a pair of lines in the power cable to the power receiver, the power transmitter further configured to perform a safety check to detect a fault with respect to the pair of lines; and the power receiver configured to receive power from the pair of lines in the power cable, and configured to perform a safety check to detect a fault with respect to the pair of lines, wherein the power transmitter further includes a transmitter synchronization circuit and the power receiver further includes a receiver synchronization circuit in communication with the transmitter synchronization circuit of the power transmitter via the synchronization cable, wherein the transmitter synchronization circuit is configured to generate a synchronization clock signal sent to the receiver synchronization circuit via the synchronization cable.

In some aspects, the techniques described herein relate to a system, wherein the receiver synchronization circuit is configured to synchronize fault detection operations of the safety check performed by the power receiver with respect to fault detection operations of the safety check performed by the power transmitter.

In some aspects, the techniques described herein relate to a system, wherein the power transmitter further includes a transmitter safety check circuit coupled to the transmitter synchronization circuit, wherein the transmitter safety check circuit is responsive to the synchronization clock signal to determine when to cause switches, connected to the pair of lines at the power transmitter, to disconnect from the pair of lines for a safety check time interval during which the fault detection operations are performed.

In some aspects, the techniques described herein relate to a system, wherein the power receiver further includes a receiver safety check circuit coupled to the receiver synchronization circuit, wherein the receiver safety check circuit is responsive to a control from the receiver synchronization circuit to determine when to cause switches, connected to the pair of lines, to disconnect from the pair of lines for a safety check time interval during which the receiver safety check circuit is configured to detect a fault.

In some aspects, the techniques described herein relate to a system, wherein the synchronization clock signal is a differential signal.

In some aspects, the techniques described herein relate to a system, wherein the transmitter synchronization circuit includes: a digital signal processor configured to generate a differential pulse width modulated (PWM) synchronization clock signal to be output over the synchronization cable and to be used by the power transmitter to determine when to cause switches, connected to the pair of lines at the power transmitter, to disconnect from the pair of lines.

In some aspects, the techniques described herein relate to a system, wherein the receiver synchronization circuit includes: a digital signal processor configured to receive the differential PWM synchronization clock signal over the synchronization cable and to use the differential PWM synchronization clock signal to control when to cause switches, connected to the pair of lines at the power receiver, to disconnect from the pair of lines.

In some aspects, the techniques described herein relate to a system, wherein the power transmitter is configured to send the differential PWM synchronization clock signal over a first output of a pair of differential outputs to a first input of a pair of differential inputs of the power receiver, and the power receiver is configured to loop back the differential PWM synchronization clock signal via a second input of the pair of differential inputs to a second output of the pair of differential outputs of the power transmitter, and the power transmitter is configured to derive a measure of propagation delay between the power transmitter and the power receiver in order to provide a pre-delay to the differential PWM synchronization clock signal to account for the propagation delay.

In some aspects, the techniques described herein relate to a system, wherein the power transmitter includes an authentication module and a security module, and is configured to send to the power receiver an authentication key and a security key, and the power receiver includes an authentication module and a security module, and is configured to receive the authentication key and the security key sent from the power transmitter and to evaluate the authentication key and the security key of the power transmitter to validate that the power transmitter is a certified power transmitter and can be trusted, and the power receiver is configured to send to the power transmitter the authentication key and security key of the power receiver to enable the power transmitter to validate that the power receiver is a certified power receiver and can be trusted.

In some aspects, the techniques described herein relate to a method including: connecting a power cable between a power transmitter and a power receiver; connecting a synchronization cable between the power transmitter and the power receiver; transmitting, by the power transmitter, power over a pair of lines in the power cable to the power receiver and performing a safety check on the pair of lines at the power transmitter; receiving, by the power receiver, the power over the pair of lines in the power cable from the power transmitter, and performing a safety check to detect a fault with respect to the pair of lines at the power receiver; transmitting, by the power transmitter over the synchronization cable, a synchronization clock signal to the power receiver; receiving, by the power receiver over the synchronization cable, the synchronization clock signal from the power transmitter; and synchronizing fault detection operations of the safety check performed by the power receiver with respect to fault detection operations of the safety check performed by the power transmitter.

In some aspects, the techniques described herein relate to a method, wherein synchronizing includes: determining, based on the synchronization clock signal, when to cause switches, connected to the pair of lines at the power transmitter, to disconnect from the pair of lines for a safety check time interval during which the fault detection operations are performed by the power transmitter; and determining, based on the synchronization clock signal, when to cause switches, connected to the pair of lines at the power receiver, to disconnect from the pair of lines for a safety check time interval during which the fault detection operations are performed by the power receiver.

In some aspects, the techniques described herein relate to a method, wherein the synchronization clock signal is a differential signal.

In some aspects, the techniques described herein relate to a method, further including: at the power transmitter, generating a differential pulse width modulated (PWM) synchronization clock signal to be output over the synchronization cable to be used by the power transmitter to determine when to cause switches, connected to the pair of lines at the power transmitter, to disconnect from the pair of lines; and at the power receiver, receiving the differential PWM synchronization clock signal over the synchronization cable to use the differential PWM synchronization clock signal to control when to cause switches, connected to the pair of lines at the power receiver, to disconnect from the pair of lines.

In some aspects, the techniques described herein relate to a method, further including: at the power transmitter, sending the differential PWM synchronization clock signal over a first output of a pair of differential outputs to a first input of a pair of differential inputs of the power receiver; at the power receiver, receiving the differential PWM synchronization clock signal via the first input to loop back the differential PWM synchronization clock signal via a second input of the pair of differential inputs to a second output of the pair of differential outputs of the power transmitter; and at the power transmitter, deriving a measure of propagation delay between the power transmitter and the power receiver in order to provide a pre-delay to the differential PWM synchronization clock signal to account for the propagation delay.

In some aspects, the techniques described herein relate to a method, further including: at the power transmitter, sending to the power receiver an authentication key and a security key; at the power receiver, receiving the authentication key and the security key sent from the power transmitter and evaluating the authentication key and the security key of the power transmitter to validate that the power transmitter is a certified power transmitter and can be trusted; and sending from the power receiver to the power transmitter an authentication key and a security key of the power receiver to enable the power transmitter to validate that the power receiver is a certified power receiver and can be trusted.

In some aspects, the techniques described herein relate to a system including: a power transmitter configured to output a power waveform, the power transmitter including a transmitter synchronization circuit and a transmitter safety check circuit, the transmitter synchronization circuit configured to generate a synchronization clock signal that synchronizes operation of the transmitter safety check circuit; a plurality of power receivers connected in a multi-drop arrangement, a first power receiver of the plurality of power receivers being connected to the power transmitter; a power cable including a pair of conductors to carry power from the power transmitter to the first power receiver; and a synchronization cable including a pair of conductors to carry the synchronization clock signal from the power transmitter to the first power receiver; wherein each power receiver of the plurality of power receivers includes: differential power inputs to receive the power waveform; differential power outputs to output the power waveform to a downstream power receiver of the plurality of power receivers; a receiver safety check circuit; differential synchronization inputs to receive the synchronization clock signal for use by the receiver safety check circuit; differential synchronization outputs to output the synchronization clock signal to a downstream power receiver; and a receiver synchronization circuit that controls the receiver safety check circuit based on the synchronization clock signal.

In some aspects, the techniques described herein relate to a system, wherein: the transmitter safety check circuit is responsive to the synchronization clock signal to determine when to cause switches, connected to the pair of lines at the power transmitter, to disconnect from the pair of lines for a safety check time interval during which the transmitter safety check circuit detects a fault; and the receiver safety check circuit is responsive to control by the receiver synchronization circuit to determine when to cause switches, connected to the pair of lines in the power cable, to disconnect from the pair of lines for a safety check time interval during which the receiver safety check circuit is detects a fault.

In some aspects, the techniques described herein relate to a system, wherein, during an initialization stage, each of the plurality of power receivers connects its differential synchronization outputs to each other, while the power transmitter transmits a first synchronization pulse to a first input of the differential synchronization inputs of the first power receiver, each power receiver of the plurality of power receivers transmitting the first synchronization pulse to a first input of the differential synchronization inputs of a downstream power receiver, and each power receiver of the plurality of power receivers monitoring a second input of the differential synchronization outputs to determine whether there is a return of the first synchronization pulse from a downstream power receiver, and in response, disconnecting a connection of its differential synchronization outputs to each other, thereby indicating to each power receiver whether there is a downstream power receiver.

In some aspects, the techniques described herein relate to a system, wherein the power transmitter sends a second synchronization pulse to the first power receiver, which forwards it to a next power receiver of the plurality of power receivers, until reaching a last power receiver in the multi-drop arrangement, which loops the second synchronization pulse back to the power transmitter via the power receivers in the multi-drop arrangement, wherein the power transmitter is configured to measure delays associated with propagation of the second synchronization pulse through the plurality of power receivers based on measurements obtained from each of the plurality of power receivers and is configured add a pre-delay to the synchronization clock signal to cause each of the plurality of power receivers to wait out a respective delay before initiating a safety check operation.

In some aspects, the techniques described herein relate to a system, wherein the power transmitter includes an authentication module and a security module, and is configured to send to each power receiver an authentication key and a security key, and each power receiver includes an authentication module and a security module, and is configured to receive the authentication key and the security key sent from the power transmitter and to evaluate the authentication key and the security key of the power transmitter to validate that the power transmitter is a certified power transmitter and can be trusted, and each power receiver is configured to send to the power transmitter the authentication key and security key of the power receiver to enable the power transmitter to validate that each power receiver is a certified power receiver and can be trusted.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. A system comprising:
a power transmitter;
a power receiver;
a power cable connected between the power transmitter and the power receiver; and
a synchronization cable connected between the power transmitter and the power receiver;
the power transmitter being coupled to receive Direct Current (DC) power and to transmit power, derived from the DC power, over a pair of lines in the power cable to the power receiver, the power transmitter further configured to perform a safety check to detect a fault with respect to the pair of lines; and
the power receiver configured to receive power from the pair of lines in the power cable, and configured to perform a safety check to detect a fault with respect to the pair of lines,
wherein the power transmitter further includes a transmitter synchronization circuit and the power receiver further includes a receiver synchronization circuit in communication with the transmitter synchronization circuit of the power transmitter via the synchronization cable, wherein the transmitter synchronization circuit is configured to generate a synchronization clock signal sent to the receiver synchronization circuit via the synchronization cable.

2. The system of claim 1, wherein the receiver synchronization circuit is configured to synchronize fault detection operations of the safety check performed by the power receiver with respect to fault detection operations of the safety check performed by the power transmitter.

3. The system of claim 2, wherein the power transmitter further comprises a transmitter safety check circuit coupled to the transmitter synchronization circuit, wherein the transmitter safety check circuit is responsive to the synchronization clock signal to determine when to cause switches, connected to the pair of lines at the power transmitter, to disconnect from the pair of lines for a safety check time interval during which the fault detection operations are performed.

4. The system of claim 3, wherein the power receiver further comprises a receiver safety check circuit coupled to the receiver synchronization circuit, wherein the receiver safety check circuit is responsive to a control from the receiver synchronization circuit to determine when to cause switches, connected to the pair of lines, to disconnect from the pair of lines for a safety check time interval during which the receiver safety check circuit is configured to detect a fault.

5. The system of claim 4, wherein the synchronization clock signal is a differential signal.

6. The system of claim 5, wherein the transmitter synchronization circuit comprises:
a digital signal processor configured to generate a differential pulse width modulated (PWM) synchronization clock signal to be output over the synchronization cable and to be used by the power transmitter to determine when to cause switches, connected to the pair of lines at the power transmitter, to disconnect from the pair of lines.

7. The system of claim 6, wherein the receiver synchronization circuit comprises:
a digital signal processor configured to receive the differential PWM synchronization clock signal over the synchronization cable and to use the differential PWM synchronization clock signal to control when to cause switches, connected to the pair of lines at the power receiver, to disconnect from the pair of lines.

8. The system of claim 7, wherein the power transmitter is configured to send the differential PWM synchronization clock signal over a first output of a pair of differential outputs to a first input of a pair of differential inputs of the power receiver, and the power receiver is configured to loop back the differential PWM synchronization clock signal via a second input of the pair of differential inputs to a second output of the pair of differential outputs of the power transmitter, and the power transmitter is configured to derive a measure of propagation delay between the power transmitter and the power receiver in order to provide a pre-delay to the differential PWM synchronization clock signal to account for the propagation delay.

9. The system of claim 1, wherein the power transmitter comprises an authentication module and a security module, and is configured to send to the power receiver an authentication key and a security key, and the power receiver includes an authentication module and a security module, and is configured to receive the authentication key and the security key sent from the power transmitter and to evaluate the authentication key and the security key of the power transmitter to validate that the power transmitter is a certified power transmitter and can be trusted, and the power receiver is configured to send to the power transmitter the authentication key and security key of the power receiver to enable the power transmitter to validate that the power receiver is a certified power receiver and can be trusted.

10. A method comprising:
connecting a power cable between a power transmitter and a power receiver;
connecting a synchronization cable between the power transmitter and the power receiver;
transmitting, by the power transmitter, power over a pair of lines in the power cable to the power receiver and performing a safety check on the pair of lines at the power transmitter;
receiving, by the power receiver, the power over the pair of lines in the power cable from the power transmitter, and performing a safety check to detect a fault with respect to the pair of lines at the power receiver;
transmitting, by the power transmitter over the synchronization cable, a synchronization clock signal to the power receiver;
receiving, by the power receiver over the synchronization cable, the synchronization clock signal from the power transmitter; and
synchronizing fault detection operations of the safety check performed by the power receiver with respect to fault detection operations of the safety check performed by the power transmitter.

11. The method of claim 10, wherein synchronizing comprises:
determining, based on the synchronization clock signal, when to cause switches, connected to the pair of lines at the power transmitter, to disconnect from the pair of lines for a safety check time interval during which the fault detection operations are performed by the power transmitter; and
determining, based on the synchronization clock signal, when to cause switches, connected to the pair of lines at the power receiver, to disconnect from the pair of lines for a safety check time interval during which the fault detection operations are performed by the power receiver.

12. The method of claim 11, wherein the synchronization clock signal is a differential signal.

13. The method of claim 12, further comprising:
at the power transmitter, generating a differential pulse width modulated (PWM) synchronization clock signal to be output over the synchronization cable to be used by the power transmitter to determine when to cause switches, connected to the pair of lines at the power transmitter, to disconnect from the pair of lines; and
at the power receiver, receiving the differential PWM synchronization clock signal over the synchronization cable to use the differential PWM synchronization clock signal to control when to cause switches, connected to the pair of lines at the power receiver, to disconnect from the pair of lines.

14. The method of claim 13, further comprising:
at the power transmitter, sending the differential PWM synchronization clock signal over a first output of a pair of differential outputs to a first input of a pair of differential inputs of the power receiver;
at the power receiver, receiving the differential PWM synchronization clock signal via the first input to loop back the differential PWM synchronization clock signal via a second input of the pair of differential inputs to a second output of the pair of differential outputs of the power transmitter; and
at the power transmitter, deriving a measure of propagation delay between the power transmitter and the power receiver in order to provide a pre-delay to the differential PWM synchronization clock signal to account for the propagation delay.

15. The method of claim 10, further comprising:
at the power transmitter, sending to the power receiver an authentication key and a security key;
at the power receiver, receiving the authentication key and the security key sent from the power transmitter and evaluating the authentication key and the security key of the power transmitter to validate that the power transmitter is a certified power transmitter and can be trusted; and
sending from the power receiver to the power transmitter an authentication key and a security key of the power receiver to enable the power transmitter to validate that the power receiver is a certified power receiver and can be trusted.

16. A system comprising:
a power transmitter configured to output a power waveform, the power transmitter including a transmitter synchronization circuit and a transmitter safety check circuit, the transmitter synchronization circuit configured to generate a synchronization clock signal that synchronizes operation of the transmitter safety check circuit;
a plurality of power receivers connected in a multi-drop arrangement, a first power receiver of the plurality of power receivers being connected to the power transmitter;
a power cable including a pair of conductors to carry power from the power transmitter to the first power receiver; and
a synchronization cable including a pair of conductors to carry the synchronization clock signal from the power transmitter to the first power receiver;
wherein each power receiver of the plurality of power receivers includes:
differential power inputs to receive the power waveform;
differential power outputs to output the power waveform to a downstream power receiver of the plurality of power receivers;
a receiver safety check circuit;
differential synchronization inputs to receive the synchronization clock signal for use by the receiver safety check circuit;
differential synchronization outputs to output the synchronization clock signal to a downstream power receiver; and
a receiver synchronization circuit that controls the receiver safety check circuit based on the synchronization clock signal.

17. The system of claim 16, wherein:
the transmitter safety check circuit is responsive to the synchronization clock signal to determine when to cause switches, connected to the pair of lines at the power transmitter, to disconnect from the pair of lines for a safety check time interval during which the transmitter safety check circuit detects a fault; and
the receiver safety check circuit is responsive to control by the receiver synchronization circuit to determine when to cause switches, connected to the pair of lines in the power cable, to disconnect from the pair of lines for a safety check time interval during which the receiver safety check circuit is detects a fault.

18. The system of claim 16, wherein, during an initialization stage, each of the plurality of power receivers connects its differential synchronization outputs to each other, while the power transmitter transmits a first synchronization pulse to a first input of the differential synchronization inputs of the first power receiver, each power receiver of the plurality of power receivers transmitting the first synchronization pulse to a first input of the differential synchronization inputs of a downstream power receiver, and each power receiver of the plurality of power receivers monitoring a second input of the differential synchronization outputs to determine whether there is a return of the first synchronization pulse from a downstream power receiver, and in response, disconnecting a connection of its differential synchronization outputs to each other, thereby indicating to each power receiver whether there is a downstream power receiver.

19. The system of claim 18, wherein the power transmitter sends a second synchronization pulse to the first power receiver, which forwards it to a next power receiver of the plurality of power receivers, until reaching a last power receiver in the multi-drop arrangement, which loops the second synchronization pulse back to the power transmitter via the power receivers in the multi-drop arrangement, wherein the power transmitter is configured to measure delays associated with propagation of the second synchronization pulse through the plurality of power receivers based on measurements obtained from each of the plurality of power receivers and is configured add a pre-delay to the synchronization clock signal to cause each of the plurality of power receivers to wait out a respective delay before initiating a safety check operation.

20. The system of claim 16, wherein the power transmitter comprises an authentication module and a security module, and is configured to send to each power receiver an authentication key and a security key, and each power receiver includes an authentication module and a security module, and is configured to receive the authentication key and the security key sent from the power transmitter and to evaluate the authentication key and the security key of the power transmitter to validate that the power transmitter is a certified power transmitter and can be trusted, and each power receiver is configured to send to the power transmitter the authentication key and security key of the power receiver to enable the power transmitter to validate that each power receiver is a certified power receiver and can be trusted.
